(19) United States
(12) Patent Application Publication
(10) Pub. No.: US 2026/0173932 A1
(43) Pub. Date: Jun. 18, 2026

(54) WIRING SUBSTRATE

(71) Applicant: Shinko Electric Industries Co., LTD., Nagano-shi (JP)

(72) Inventor: Ryota Hoshina, Nagano-shi (JP)

(73) Assignee: Shinko Electric Industries Co., LTD., Nagano-shi (JP)

(21) Appl. No.: 19/415,000

(22) Filed: Dec. 10, 2025

(30) Foreign Application Priority Data
Dec. 12, 2024 (JP) 2024-217762

(51) Int. Cl. H10W 70/68; H10W 70/685

(52) U.S. Cl. CPC H10W 70/682; H10W 70/685

(57) ABSTRACT

A wiring substrate includes a first insulation layer, first and second wiring layers formed on the first insulation layer, a second insulation layer covering side and upper surfaces the first and second wiring layers, N insulation layers stacked on the second insulation layer, a cavity formed in the N insulation layers and exposing a first surface of the second insulation layer, an opening formed in the first surface to expose part of the upper surface of the first wiring layer, a connection terminal formed on the first wiring layer exposed from the opening, an electronic component arranged in the cavity and mounted on the connection terminal, a capping insulation layer filling the cavity and covering the electronic component, a third wiring layer formed on the capping insulation layer. In plan view, the first wiring layer overlaps the cavity and the second wiring layer does not overlap the cavity.

### CROSS-REFERENCE TO RELATED APPLICATIONS

This application is based upon and claims the benefit of priority from Japanese Patent Application No. 2024-217762, filed on Dec. 12, 2024, the entire contents of which are incorporated herein by reference.

### BACKGROUND

### 1. Field

The present disclosure relates to a wiring substrate and a method for manufacturing a wiring substrate.

### 2. Description of Related Art

JP2022-80677A describes a wiring substrate that incorporates an electronic component. Such a wiring substrate may include multiple insulation layers, a cavity formed in the insulation layers, and a conductive pad exposed from the bottom of the cavity. An electronic component is mounted on the conductive pad. The cavity is filled with a capping insulation layer so that the capping insulation layer covers the electronic component. The wiring substrate may be manufactured, for example, in the following manner. First, the conductive pad is formed and covered by a protective material. Then, a stack of the insulation layers is formed so as to cover the conductive pad and the protective material. A given region of the insulation layers is removed to form a cavity exposing the protective material. Then, the protective material is removed to expose the conductive pad. The electronic component is mounted on the conductive pad. Then, the capping insulation layer is formed to fill the cavity and cover the electronic component.

### SUMMARY

In the wiring substrate, it is desirable that the filling factor of the capping insulation layer is improved.

In an aspect of the present disclosure, a wiring substrate includes a first insulation layer, a first wiring layer and a second wiring layer that are formed on an upper surface of the first insulation layer, a second insulation layer formed on the upper surface of the first insulation layer to cover a side surface and an upper surface of the first wiring layer and a side surface and an upper surface of the second wiring layer, N number of insulation layers stacked on an upper surface of the second insulation layer where N is a natural number greater than or equal to 1, a cavity formed in the N number of insulation layers and exposing a first surface of the second insulation layer, an opening formed in the first surface and extending through the second insulation layer in a thickness-wise direction to expose part of the upper surface of the first wiring layer, a connection terminal formed on the upper surface of the first wiring layer exposed from the opening, an electronic component arranged in the cavity and mounted on the connection terminal, a capping insulation layer filling the cavity and covering the electronic component, a third wiring layer formed on an upper surface of the capping insulation layer and electrically connected to the electronic component. The first wiring layer overlaps the cavity in plan view. The second wiring layer does not overlap the cavity in plan view.

Other features and aspects will be apparent from the following detailed description, the drawings, and the claims.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### BRIEF DESCRIPTION OF THE DRAWINGS

FIG. 1 is a schematic cross-sectional view of a wiring substrate in accordance with a first embodiment.

FIG. 2 is a schematic cross-sectional view enlarging part of the wiring substrate illustrated in FIG. 1.

FIGS. 3, 4, 5, 6, 7, 8, 9, 10, 11, 12, 13, 14, 15, 16, 17, 18, 19, and 20 are schematic cross-sectional views illustrating a method for manufacturing the wiring substrate illustrated in FIG. 1.

FIG. 21 is a schematic cross-sectional view illustrating, in an enlarged manner, part of a wiring substrate in accordance with a second embodiment.

FIGS. 22, 23, 24, 25, 26, 27, 28, 29, 30, and 31 are schematic cross-sectional views illustrating a method for manufacturing the wiring substrate in accordance with the second embodiment.

FIG. 32 is a schematic cross-sectional view illustrating, in an enlarged manner, part of a wiring substrate in accordance with a third embodiment.

FIGS. 33, 34, 35, 36, 37, and 38 are schematic cross-sectional views illustrating a method for manufacturing the wiring substrate in accordance with the third embodiment.

FIG. 39 is a schematic cross-sectional view illustrating, in an enlarged manner, part of a wiring substrate in accordance with a fourth embodiment.

FIGS. 40, 41, 42, 43, and 44 are schematic cross-sectional views illustrating a method for manufacturing the wiring substrate in accordance with the fourth embodiment.

FIGS. 45, 46, and 47 are schematic cross-sectional views illustrating, in an enlarged manner, part of the wiring substrate in modified examples.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

This description provides a comprehensive understanding of the methods, apparatuses, and/or systems described. Modifications and equivalents of the methods, apparatuses, and/or systems described are apparent to one of ordinary skill in the art. Sequences of operations are exemplary, and may be changed as apparent to one of ordinary skill in the art, with the exception of operations necessarily occurring in a certain order. Descriptions of functions and constructions that are well known to one of ordinary skill in the art may be omitted.

Exemplary embodiments may have different forms, and are not limited to the examples described. However, the examples described are thorough and complete, and convey the full scope of the disclosure to one of ordinary skill in the art.

In this specification, “at least one of A and B” should be understood to mean “only A, only B, or both A and B.”

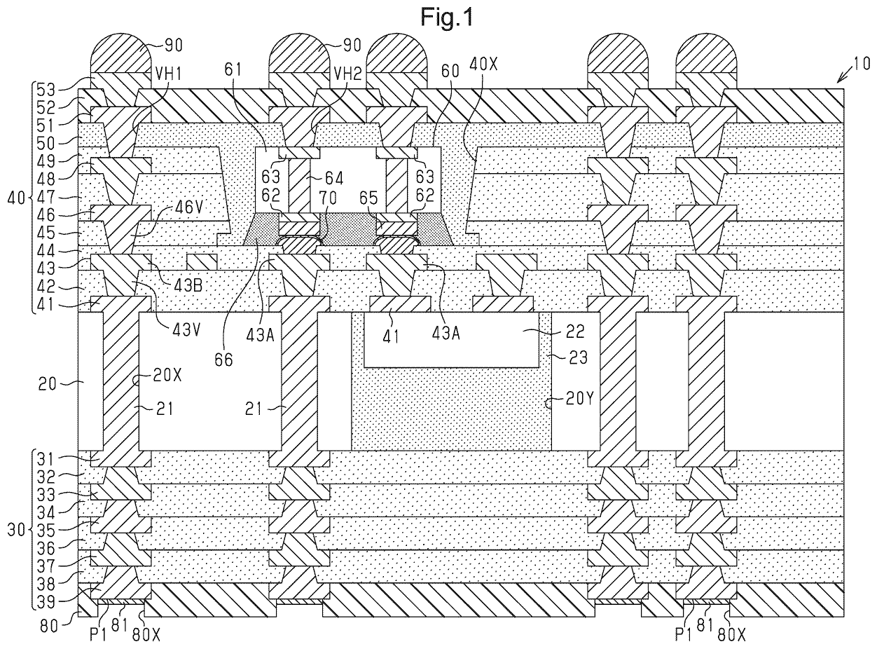

Embodiments will now be described with reference to the drawings. In the accompanying drawings, elements are illustrated for simplicity and clarity and have not necessarily been drawn to scale. In the cross-sectional views, to facilitate understanding of the cross-sectional structure of each member, hatching lines may be replaced by shadings or may not be illustrated. In this specification, a plan view refers to a view of a subject taken in a vertical direction (e.g., vertical direction as viewed in FIG. 1), and a planar shape refers to a shape of a subject as viewed in the vertical direction. Further, in this specification, upward, downward, leftward, and rightward directions refer to directions that allow for the reference characters denoting members to be read properly. In addition, in the description of the present disclosure, the numerical range of “X1 to X2” defined by an upper limit value X1 and a lower limit value X2 refers to being greater than or equal to X1 and less than or equal to X2, unless otherwise specified.

### First Embodiment

A first embodiment will now be described with reference to FIGS. 1 to 20.

### Overall Structure of the Wiring Substrate 10

As illustrated in FIG. 1, a wiring substrate 10 includes a core substrate 20, a wiring structure 30, a wiring structure 40, a cavity 40X formed in the wiring structure 40, and one or more (in the present embodiment, one) electronic components 60 arranged in the cavity 40X. The wiring substrate 10 includes an underfill resin 66, a solder resist layer 80, and external connection terminals 90. The wiring substrate 10 incorporates the electronic component 60. The wiring structure 40 and the external connection terminals 90 are arranged on one side of the core substrate 20. The wiring structure 30 and the solder resist layer 80 are arranged on the other side of the core substrate 20.

In the present embodiment, for the sake of convenience, with reference to FIG. 1, the side of the wiring substrate 10 on which the external connection terminals 90 are arranged will be referred to as “one side” or “the upper side.” The side of the wiring substrate 10 where the solder resist layer 80 is arranged will be referred to as “the other side” or “the lower side.” Additionally, in the present embodiment, a surface of a component located toward the external connection terminals 90 will be referred to as “one surface” or “the upper surface” of the component. A surface of the component located toward the solder resist layer 80 will be referred to as “the other surface” or “the lower surface” of the component. The wiring substrate 10 may be used in a state reversed, upside down, or be arranged at any angle.

The core substrate 20 may be, for example, a glass epoxy substrate in which a glass cloth is impregnated with a thermosetting insulating resin, such as an epoxy resin, or the like. The core substrate 20 may be, for example, a substrate in which a woven cloth or non-woven cloth of glass fibers, carbon fibers, aramid fibers, or the like, is impregnated with a thermosetting insulating resin, such as an epoxy resin or the like. The drawings do not illustrate a glass cloth or the like.

Multiple through holes 20X extend through the core substrate 20 in the thickness-wise direction of the core substrate 20. In each through hole 20X, a through-electrode 21 extends through the core substrate 20 in the thickness-wise direction. In an example, the through-electrodes 21 fill the through holes 20X. The material of the through-electrodes 21 may be, for example, copper (Cu) or a copper alloy.

The core substrate 20 includes one or more (in the present embodiment, one) openings 20Y extending through the core substrate 20 in the thickness-wise direction. An electronic component 22 is accommodated in the opening 20Y. The opening 20Y is filled with a resin portion 23 that covers the electronic component 22. The resin portion 23 covers, for example, the lower surface and the side surfaces of the electronic component 22. The electronic component 22 may be, for example, a semiconductor element, a crystal oscillator, or a chip component. Examples of a chip component include a chip capacitor, a chip resistor, and a chip inductor. The electronic component 22 incorporated in the core substrate 20 does not have to be of a single type. Different types of electronic components 22 may be incorporated in the core substrate 20. The material of the resin portion 23 may be, for example, an insulating resin such as an epoxy resin.

### Structure of the Wiring Structure 30

The wiring structure 30 is formed on the lower surface of the core substrate 20. The wiring structure 30 of the present embodiment includes a structure in which a wiring layer 31, an insulation layer 32, a wiring layer 33, an insulation layer 34, a wiring layer 35, an insulation layer 36, a wiring layer 37, an insulation layer 38, and a wiring layer 39 are sequentially formed on the lower surface of the core substrate 20.

The material of the wiring layers 31, 33, 35, 37, and 39 may be, for example, copper or a copper alloy. The thickness of each of the wiring layers 31, 33, 35, 37, and 39 may be, for example, approximately 8 μm to 35 μm.

The insulation layers 32, 34, 36, and 38 include a non-photosensitive resin as a main component. The main component of the insulation layers 32, 34, 36, and 38 may be, for example, a thermosetting non-photosensitive resin, such as an epoxy resin, an imide resin, a phenol resin, a cyanate resin, or the like. The thickness of each of the insulation layers 32, 34, 36, and 38 may be, for example, approximately 35 μm to 100 μm.

The wiring layer 31 is formed on the lower surface of the core substrate 20. The wiring layer 31 is electrically connected to the through-electrodes 21. The insulation layer 32 is formed on the lower surface of the core substrate 20 to cover the wiring layer 31. The wiring layer 33 is formed on the lower surface of the insulation layer 32. The wiring layer 33 is electrically connected to the wiring layer 31 by via wiring extending through the insulation layer 32 in the thickness-wise direction.

The insulation layer 34 is formed on the lower surface of the insulation layer 32 to cover the wiring layer 33. The wiring layer 35 is formed on the lower surface of the insulation layer 34. The wiring layer 35 is electrically connected to the wiring layer 33 by via wiring extending through the insulation layer 34 in the thickness-wise direction. The insulation layer 36 is formed on the lower surface of the insulation layer 34 to cover the wiring layer 35. The wiring layer 37 is formed on the lower surface of the insulation layer 36. The wiring layer 37 is electrically connected to the wiring layer 35 by via wiring extending through the insulation layer 36 in the thickness-wise direction. The insulation layer 38 is formed on the lower surface of the insulation layer 36 to cover the wiring layer 37. The wiring layer 39 is formed on the lower surface of the insulation layer 38. The wiring layer 39 is electrically connected to the wiring layer 37 by via wiring extending through the insulation layer 38 in the thickness-wise direction.

### Structure of the Solder Resist Layer 80

The solder resist layer 80 is the outermost insulation layer (in this case, lowermost insulation layer) of the wiring substrate 10. The solder resist layer 80 is formed on the lower surface of the insulation layer 38 to cover the wiring layer 39, which is the lowermost layer. The solder resist layer 80 is an insulation layer including a photosensitive resin as a main component. The material of the solder resist layer 80 may be, for example, a photosensitive insulating resin including a phenol resin, a polyimide resin, or the like, as a main component.

The solder resist layer 80 includes openings 80X that expose parts of the lower surface of the lowermost wiring layer 39 as external connection pads P1. The external connection pads P1 are connected to external connection terminals used to mount the wiring substrate 10 on a mount substrate, such as a motherboard or the like.

A surface-processed layer 81 is formed on the parts of the wiring layer 39 exposed from the openings 80X. The surface-processed layer 81 may be an Au layer, a Ni layer/Au layer (metal layer formed by stacking a Ni layer and an Au layer in this order), or a Ni layer/Pd layer/Au layer (metal layer formed by stacking a Ni layer, a Pd layer, and an Au layer in this order). The Au layer is a metal layer formed from Au or an Au alloy. The Ni layer is a metal layer formed from Ni or a Ni alloy. The Pd layer is a metal layer formed from Pd or a Pd alloy. Each of the Au layer, the Ni layer, and the Pd layer may be, for example, a metal layer formed through an electroless plating process (electroless plated layer). Alternatively, the surface-processed layer 81 may be an organic solderability preservative (OSP) film formed by performing an oxidation-resisting process, such as an OSP process, on the surface of the external connection pads P1. The OSP film may be, for example, a coating of an organic compound such as an azole compound or an imidazole compound. The wiring layer 39 exposed in the openings 80X (or surface-processed layer 81, if the surface-processed layer 81 is formed on the wiring layer 39) may be used as external connection terminals.

### Structure of the Wiring Structure 40

The wiring structure 40 is stacked on the upper surface of the core substrate 20. The wiring structure 40 has a structure obtained by sequentially stacking a wiring layer 41, an insulation layer 42, a wiring layer 43, an insulation layer 44, an insulation layer 45, a wiring layer 46, an insulation layer 47, a wiring layer 48, an insulation layer 49, an insulation layer 50, a wiring layer 51, an insulation layer 52, and a wiring layer 53 on the upper surface of the core substrate 20.

The material of the wiring layers 41, 43, 46, 48, 51, and 53 may be, for example, copper or a copper alloy. The thickness of the wiring layers 41, 43, 46, 48, 51, 53 may be, for example, approximately 10 μm to 30 μm.

The insulation layers 42, 44, 45, 47, 49, 50, and 52 each include, for example, a non-photosensitive resin as a main component. The main component of the insulation layers 42, 44, 45, 47, 49, 50, and 52 may be, for example, a thermosetting non-photosensitive resin, such as an epoxy resin, an imide resin, a phenol resin, a cyanate resin, or the like. The insulation layer 52 may include a photosensitive resin as a main component, in the same manner as the solder resist layer 80. In this case, the material of the insulation layer 52 may be, for example, a photosensitive insulating resin including a phenol resin, a polyimide resin, or the like, as a main component.

The wiring layer 41 is formed on the upper surface of the core substrate 20. Parts of the wiring layer 41 are electrically connected to the wiring layer 31 by the through-electrodes 21. Parts of the wiring layer 41 are electrically connected to the electronic component 22. The insulation layer 42 is formed on the upper surface of the core substrate 20 and covers the wiring layer 41. The insulation layer 42 covers the upper surface of the electronic component 22 and the upper surface of the resin portion 23. The thickness from the upper surface of the wiring layer 41 to the upper surface of the insulation layer 42 may be, for example, approximately 20 μm to 60 μm.

The wiring layer 43 is formed on the upper surface of the insulation layer 42. The wiring layer 43 is electrically connected to the wiring layer 41 by via wirings 43V extending through the insulation layer 42 in the thickness-wise direction. The wiring layer 43 includes a wiring layer 43A and a wiring layer 43B. The wiring layer 43A overlaps the cavity 40X in plan view. The wiring layer 43B does not overlap the cavity 40X in plan view.

The insulation layer 44 is formed on the upper surface of the insulation layer 42 to cover the wiring layer 43. The insulation layer 44 covers the upper surface and the side surface of the wiring layer 43. The thickness from the upper surface of the wiring layer 43 to the upper surface of the insulation layer 44 may be, for example, approximately 5 μm to 20 μm.

The insulation layer 45 is formed on the upper surface of the insulation layer 44. The insulation layer 45 covers the upper surface of the insulation layer 44. The thickness from the upper surface of the insulation layer 44 to the upper surface of the insulation layer 45 may be, for example, approximately 20 μm to 45 μm.

The wiring layer 46 is formed on the upper surface of the insulation layer 45. The wiring layer 46 is electrically connected to the wiring layer 43B by via wirings 46V extending through the insulation layers 44 and 45 in the thickness-wise direction. The wiring layer 46 does not overlap the cavity 40X in plan view.

The insulation layer 47 is formed on the upper surface of the insulation layer 45 to cover the wiring layer 46. The thickness from the upper surface of the wiring layer 46 to the upper surface of the insulation layer 47 is, for example, approximately 20 μm to 60 μm.

The wiring layer 48 is formed on the upper surface of the insulation layer 47. The wiring layer 48 is electrically connected to the wiring layer 46 by via wiring extending through the insulation layer 47 in the thickness-wise direction. The wiring layer 48 does not overlap the cavity 40X in plan view.

The insulation layer 49 is formed on the upper surface of the insulation layer 47 to cover the wiring layer 48. The thickness from the upper surface of the wiring layer 48 to the upper surface of the insulation layer 49 may be, for example, approximately 20 μm to 45 μm.

The cavity 40X is formed in the insulation layers 45, 47, and 49. The cavity 40X is recessed downward from the upper surface of the insulation layer 49. The cavity 40X extends through the insulation layers 45, 47, and 49 in the thickness-wise direction. The cavity 40X is formed in correspondence with the electronic component 60 that will be incorporated. That is, the cavity 40X is formed at a mount position of the electronic component 60.

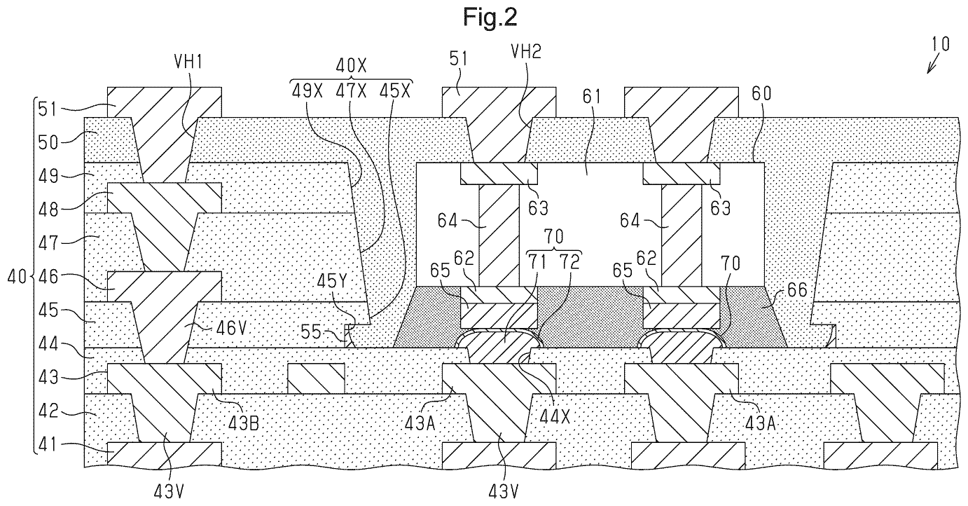

As illustrated in FIG. 2, in the present embodiment, the cavity 40X includes a through hole 49X extending through the insulation layer 49 in the thickness-wise direction, a through hole 47X extending through the insulation layer 47 in the thickness-wise direction, and a through hole 45X extending through the insulation layer 45 in the thickness-wise direction. The through holes 49X, 47X, and 45X are continuous with each other. In an example, the wall surface of the through hole 49X, the wall surface of the through hole 47X, and the wall surface of the through hole 45X are continuous with each other. The through holes 49X, 47X, and 45X are, for example, coaxial with each other. That is, the through holes 49X, 47X, and 45X share the same center axis in plan view. The cavity 40X exposes, for example, part of the upper surface of the insulation layer 44. In other words, the bottom surface of the cavity 40X is defined by the upper surface of the insulation layer 44. The depth of the cavity 40X, that is, the thickness from the upper surface of the insulation layer 44 to the upper surface of the insulation layer 49 may be, for example, approximately 80 μm to 200 μm.

The cavity 40X is, for example, tapered so that the width decreases from the upper side (upper surface of insulation layer 49) toward the lower side (insulation layer 44), as viewed in FIG. 2. That is, the cavity 40X widens from the lower side toward the upper side. The space surrounded by the wall surface of the cavity 40X and the bottom surface of the cavity 40X, that is, the inside of the cavity 40X, serves as an accommodation space for the electronic component 60.

As described above, in the wiring substrate 10 of the present embodiment, the three insulation layers 45, 47, and 49 stacked on the insulation layer 44 serve as insulation layers in which the cavity is formed. FIG. 2 does not illustrate the insulation layer 52, the wiring layer 53, and the external connection terminals 90 to simplify illustration.

A recess 45Y is formed in a lower end of the insulation layer 45, which forms a wall surface of the cavity 40X. For example, of the wall surfaces of the cavity 40X, a wall surface that is in contact with the insulation layer 44 is recessed into the insulation layer 45, which forms the recess 45Y. The recess 45Y is continuous with the cavity 40X. Thus, the recess 45Y is formed at the bottom of the cavity 40X to widen the cavity 40X.

The recess 45Y is formed, for example, along the entire perimeter of the cavity 40X. Alternatively, the recess 45Y may be formed in part of the perimeter of the cavity 40X. The dimension of the recess 45Y in the thickness-wise direction (vertical direction in FIG. 2) of the insulation layer 45, that is, the depth of the recess 45Y, is, for example, smaller than the thickness of the wiring layer 46. The depth of the recess 45Y may be, for example, approximately 5 μm to 25 μm.

In an example, a metal layer 55 is formed in the recess 45Y. The metal layer 55 is in contact with the upper surface of the insulation layer 44. The metal layer 55 is in contact with an inner wall surface of the recess 45Y. When the metal layer 55 is formed, the recess 45Y is defined by a space surrounded by the metal layer 55, the lower surface of the insulation layer 45 exposed from the metal layer 55, and the upper surface of the insulation layer 44 exposed from the metal layer 55.

Openings 44X are formed in the upper surface of the insulation layer 44 exposed from the cavity 40X. The openings 44X extend through the insulation layer 44 in the thickness-wise direction to expose parts of the upper surface of the wiring layer 43A. Each opening 44X is, for example, tapered so that the width decreases from the upper side (upper surface of insulation layer 44) toward the lower side (wiring layer 43A), as viewed in FIG. 2.

The electronic component 60 is mounted on the parts of the wiring layer 43A exposed from the cavity 40X and the openings 44X. The wiring layer 43A serves as conductive pads for electronic component mounting so that the electronic component 60 is electrically connected.

Connection terminals 70 are formed on the parts of the upper surface of the wiring layer 43A exposed from the openings 44X. The connection terminals 70 cover the entire upper surface of the wiring layer 43A exposed from the openings 44X. The connection terminals 70 may be, for example, a metal layer such as an Au layer, a Ni layer/Au layer, or a Ni layer/Pd layer/Au layer.

In the present embodiment, the connection terminals 70 have a structure in which a first metal layer 71 and a second metal layer 72 are stacked.

The first metal layer 71 covers the entire upper surface of the wiring layer 43A exposed from the openings 44X. In an example, the first metal layer 71 fills the openings 44X. In an example, the first metal layer 71 projects upward from the upper surface of the insulation layer 44. In an example, parts of the first metal layer 71 projecting upward from the upper surface of the insulation layer 44, that is, the first metal layer 71 exposed from the insulation layer 44, project outward from the openings 44X in a planar direction (in FIG. 2, sideward direction) that is orthogonal to the thickness-wise direction of the insulation layer 44. In an example, the side surface of the first metal layer 71 exposed from the insulation layer 44 is curved to have an arcuate cross section. The side surface of the first metal layer 71 exposed from the insulation layer 44 is curved toward the upper surface of the first metal layer 71 and becomes closer to the planar center of the first metal layer 71. The upper surface of the first metal layer 71 is, for example, horizontally flat in the planar direction. The upper surface and the side surface of the first metal layer 71 form an upper corner of the first metal layer 71 that is curved to have an arcuate cross section. Preferably, the material of the first metal layer 71 is, for example, a conductive material having a higher adhesion to the wiring layer 43A than the metal forming the second metal layer 72. In the present embodiment, the first metal layer 71 is a Ni layer. The first metal layer 71 may be, for example, an electroless plating layer formed through an electroless plating process.

The second metal layer 72 covers the entire surface of the first metal layer 71. The second metal layer 72 covers the entire upper surface of the first metal layer 71 and the entire side surface of the first metal layer 71. The second metal layer 72 is shaped in conformance with the surface of the first metal layer 71. In the present embodiment, the second metal layer 72 is an Au layer. The second metal layer 72 may be, for example, an electroless plating layer formed through an electroless plating process. The thickness of the first metal layer 71 may be, for example, approximately 1 μm to 25 μm. The thickness of the second metal layer 72 may be, for example, approximately 10 nm to 90 nm.

### Structure of the Electronic Component 60

The structure of the electronic component 60 will now be described.

The electronic component 60 includes a main body 61, a first electrode 62 arranged on the lower surface of the main body 61, a second electrode 63 arranged on the upper surface of the main body 61, and a through-electrode 64. The electronic component 60 of the present embodiment includes multiple first electrodes 62, multiple second electrodes 63, and multiple through-electrodes 64. The electronic component 60 is, for example, flip-chip-mounted on the wiring layer 43A exposed from the openings 44X. For example, the first electrodes 62 of the electronic component 60 are electrically connected to the connection terminals 70 formed on the parts of the upper surface of the wiring layer 43A exposed in the openings 44X. For example, the first electrodes 62 are electrically connected to the connection terminals 70 by bonding members 65. Thus, the electronic component 60 is electrically connected to the wiring layer 43A by the first electrodes 62, the bonding members 65, and the connection terminals 70. As illustrated in FIG. 1, one or more of the first electrodes 62 are electrically connected to the electronic component 22 by the bonding members 65, the connection terminals 70, the wiring layer 43A, the via wirings 43V, and the wiring layer 41. One or more of the first electrodes 62 are electrically connected to the through-electrodes 21 by the bonding members 65, the connection terminals 70, the wiring layer 43A, the via wirings 43V, and the wiring layer 41.

The electronic component 60 may be, for example, a semiconductor element, a crystal oscillator, or a chip component. Examples of a chip component include a chip capacitor, a chip resistor, and a chip inductor. The electronic component 60 incorporated in the wiring substrate 10 does not have to be of a single type. Different types of electronic components 60 may be incorporated in the wiring substrate 10.

The main body 61 is, for example, box-shaped. The thickness of the main body 61 may be, for example, approximately 50 μm to 200 μm. The main body 61 is formed from, for example, silicon (Si) or silicon carbide (SiC).

The material of the first electrodes 62, the second electrodes 63, and the through-electrodes 64 may be, for example, a metal such as aluminum (Al) or copper (Cu) or an alloy including at least one of these metals.

As illustrated in FIG. 2, the first electrodes 62, for example, project downward from the lower surface of the main body 61. The thickness of each first electrode 62 may be, for example, approximately 2 μm to 20 μm. The first electrodes 62 may be embedded in the main body 61.

The second electrodes 63 are arranged opposite from the first electrodes 62. The second electrodes 63 are, for example, embedded in the main body 61. The upper surface of each second electrode 63 is exposed from the upper surface of the main body 61. The upper surface of the second electrode 63 is, for example, flush with the upper surface of the main body 61. The thickness of the second electrode 63 may be, for example, approximately 2 μm to 20 μm. The second electrode 63 may project upward from the upper surface of the main body 61.

The through-electrodes 64 extend through the main body 61 in a thickness-wise direction. The through-electrodes 64, for example, extend straight in the thickness-wise direction of the main body 61. The through-electrodes 64 electrically connect the first electrodes 62 and the second electrodes 63.

### Structure of the Bonding Member 65

The bonding members 65 are, for example, bonded to the first electrodes 62 and the connection terminals 70. The bonding members 65 electrically connect the first electrodes 62 and the connection terminals 70. The bonding members 65 may be, for example, a solder layer. The material of the solder layer may be, for example, lead (Pb)-free solder of tin (Sn)-silver (Ag), Sn—Cu, or Sn—Ag—Cu. The thickness of each bonding member 65 may be, for example, approximately 5 μm to 30 μm.

### Structure of the Underfill Resin 66

The underfill resin 66 is formed between the electronic component 60 and the bottom surface of the cavity 40X. The underfill resin 66 fills the gap between the lower surface of the main body 61 of the electronic component 60 and the bottom surface of the cavity 40X, in this embodiment, the upper surface of the insulation layer 44. The underfill resin 66 encapsulates the first electrodes 62, the bonding members 65, and the connection terminals 70. The material of the underfill resin 66 may be, for example, an insulating resin such as epoxy resin.

### Structure of the Wiring Structure 40

The insulation layer 50 is a capping insulation layer that fills the cavity 40X. The insulation layer 50 covers the upper surface of the insulation layer 49 and fills the cavity 40X to cover the electronic component 60. The insulation layer 50 fills the recess 45Y. The insulation layer 50 covers the underfill resin 66. The insulation layer 50 covers, for example, the entire side surface of the underfill resin 66. The insulation layer 50 covers, for example, the entire bottom surface of the cavity 40X exposed from the underfill resin 66. The insulation layer 50 covers, for example, the entire wall surface of the cavity 40X. The insulation layer 50, for example, entirely covers the electronic component 60 exposed from the underfill resin 66. The insulation layer 50 covers, for example, the side surface and the upper surface of the main body 61 exposed from the underfill resin 66. The insulation layer 50 covers, for example, the upper surface of the second electrodes 63.

The insulation layer 50 covers, for example, the entire upper surface of the insulation layer 49. The insulation layers 49 and 50 include through holes VH1 at given locations. The through holes VH1 extend through the insulation layers 49 and 50 in the thickness-wise direction and expose parts of the upper surface of the wiring layer 48. The insulation layer 50 includes through holes VH2 at given locations. The through holes VH2 extend through the insulation layer 50 in the thickness-wise direction and expose parts of the upper surface of the second electrodes 63. The through holes VH1 and VH2 are, for example, tapered so that the diameter (opening width) decreases from the upper side (upper surface of insulation layer 49) toward the lower side, as viewed in FIG. 2. For example, each of the through holes VH1 and VH2 has the form of a reversed truncated cone so that the opening diameter of its lower end is smaller than the opening diameter of its upper end. The thickness from the upper surface of the insulation layer 49 to the upper surface of the insulation layer 50 may be, for example, 15 μm to 45 μm.

The wiring layer 51 is formed on the upper surface of the insulation layer 50. The wiring layer 51 includes, for example, a wiring pattern electrically connected to the wiring layer 48 by via wiring filling the through holes VH1. The wiring layer 51 includes, for example, a wiring pattern electrically connected to the second electrodes 63 by via wiring filling the through holes VH2. The wiring layer 51 is, for example, formed integrally with the via wiring filling the through holes VH1 or the through holes VH2. The wiring layer 51 may be laid out on the upper surface of the insulation layer 50 in the planar direction. Further, the wiring layer 51 laid out as described above may electrically connect part of the wiring layer 51 connected to the wiring layer 48 and part of the wiring layer 51 connected to the second electrode 63.

As illustrated in FIG. 1, the insulation layer 52 is formed on the upper surface of the insulation layer 50 to cover the wiring layer 51. The insulation layer 52 is the outermost insulation layer arranged in the outermost (in this embodiment, uppermost) layer of the wiring substrate 10. The thickness from the upper surface of the wiring layer 51 to the upper surface of the insulation layer 52 may be, for example, approximately 15 μm to 40 μm.

The wiring layer 53 is formed on the upper surface of the insulation layer 52. The wiring layer 53 is electrically connected to the wiring layer 51 by via wiring extending through the insulation layer 52 in the thickness-wise direction. The wiring layer 53 is, for example, the outermost (in this embodiment, uppermost) wiring layer of the wiring substrate 10. The wiring layer 53 serves as, for example, electronic component mounting pads for electrical connection to an electronic component (not illustrated), such as a semiconductor element or the like.

A surface-processed layer may be formed on the surfaces (upper surface and side surfaces or only upper surface) of the wiring layer 53 when necessary. The surface-processed layer may be an OSP film or a metal layer, such as an Au layer, a Ni layer/Au layer, a Ni layer/Pd layer/Au layer, or the like.

The external connection terminals 90 are, for example, arranged on the upper surface of the wiring layer 53. The external connection terminals 90 may be, for example, solder balls. The material of the solder balls may be, for example, Pb-free solder of Sn-Ag, Sn—Cu, or Sn—Ag—Cu.

### Method for Manufacturing the Wiring Substrate 10

A method for manufacturing the wiring substrate 10 will now be described. To facilitate understanding, portions that ultimately become elements of the wiring substrate 10 are indicated by reference characters used to denote the final elements.

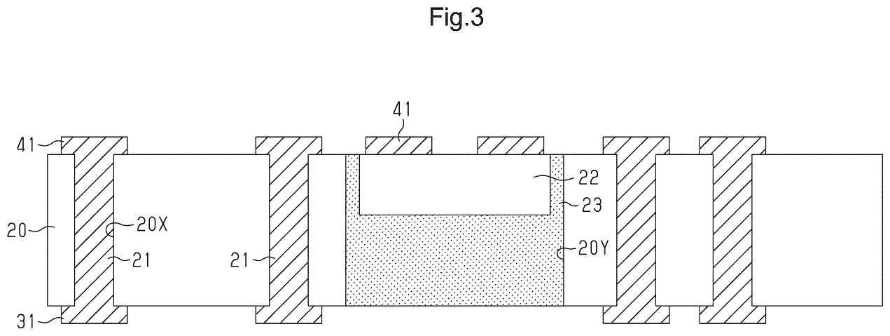

In the step illustrated in FIG. 3, a structural body is formed including the core substrate 20 having the through holes 20X and the openings 20Y, the through-electrodes 21, the electronic component 22, the resin portion 23, and the wiring layers 41 and 31 respectively formed on the upper surface and the lower surface of the core substrate 20. This structural body may be manufactured by a known process. Thus, the process will not be described in detail.

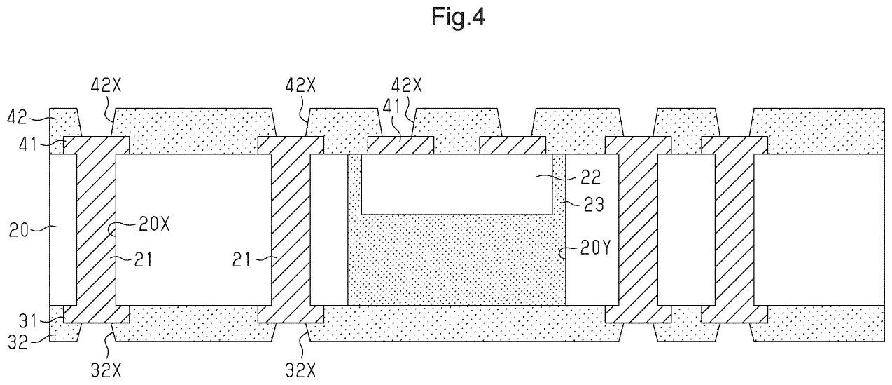

In the step illustrated in FIG. 4, the insulation layer 32 is formed on the lower surface of the core substrate 20 to cover the wiring layer 31, and the insulation layer 42 is formed on the upper surface of the core substrate 20 to cover the wiring layer 41. In an example in which a resin film is used as the insulation layers 32 and 42, the lower surface or the upper surface of the core substrate 20 is laminated with the resin film. The resin film is heated at a curing temperature or higher (e.g., approximately 130° C. to 200° C.) while being pressed so that the resin film is cured to form the insulation layers 32 and 42. The resin film may be, for example, a film of a thermosetting resin including an epoxy resin as a main component. When a liquid or paste of an insulating resin is used as the insulation layers 32 and 42, the liquid or paste of insulating resin is applied to the lower surface or the upper surface of the core substrate 20 through a spin coating process or the like. The applied insulating resin is heated at a curing temperature or higher so that the insulating resin is cured to form the insulation layers 32 and 42. The liquid or paste of insulating resin may be, for example, a thermosetting resin including an epoxy resin as a main component.

Through holes 32X are formed in the insulation layer 32 at given locations so as to partially expose the lower surface of the wiring layer 31. Through holes 42X are formed in the insulation layer 42 at given locations so as to partially expose the upper surface of the wiring layer 41. The through holes 32X and 42X may be formed by, for example, laser drilling using CO₂ laser, UV-YAG laser, or the like.

In a case in which the through holes 32X and 42X are formed by laser drilling, a desmear process is performed to remove resin smears from the surface of the wiring layers 31 and 41 exposed at the bottom of the through holes 32X and 42X. The desmear process in this step may be, for example, a wet desmear process using a potassium permanganate solution or the like.

A method for manufacturing a structural body formed on the upper surface of the core substrate 20, that is, the structural body illustrated in FIG. 2, will now be described.

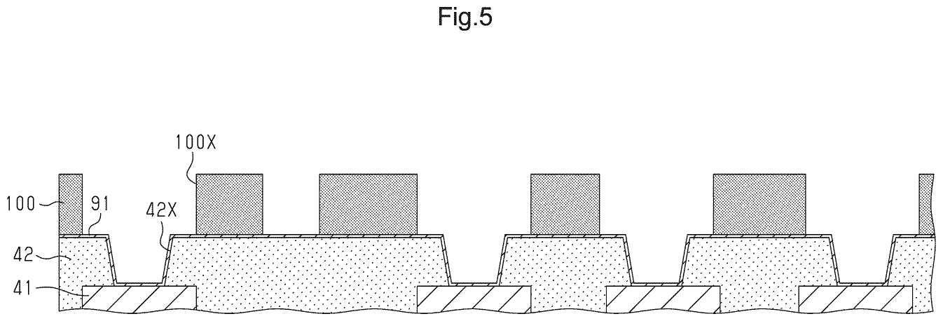

In the step illustrated in FIG. 5, a seed layer 91 is formed to cover the entire upper surface of the insulation layer 42 and the entire wall surface of the through holes 42X. The seed layer 91 may be formed by, for example, sputtering or electroless plating. In an example in which the seed layer 91 is formed by sputtering, titanium (Ti) is first sputtered and deposited on the upper surface of the insulation layer 42 and the wall surfaces of the through holes 42X, so that a Ti layer covers the upper surface of the insulation layer 42 and the wall surfaces of the through holes 42X. Then, copper is sputtered and deposited on the Ti layer to form a Cu layer. This forms the seed layer 91 having a double-layer structure (Ti layer/Cu layer). In another example in which the seed layer 91 is formed by electroless plating, electroless copper plating may be performed to form the seed layer 91 having a Cu layer (single-layer structure).

Subsequently, a resist layer 100 including an opening pattern 100X is formed on the seed layer 91 at a given location. The opening pattern 100X exposes a portion of the seed layer 91 corresponding to a region in which the wiring layer 43 (refer to FIG. 2) is formed. For example, a material having resistance to the electrolytic plating process performed in the next step may be used as the material of the resist layer 100. For example, the material of the resist layer 100 may be a photosensitive dry film resist or a liquid photoresist (e.g., dry film resist or liquid resist of novolac resin or acrylic resin). In an example in which a photosensitive dry film resist is used, the upper surface of the seed layer 91 is laminated with a dry film by thermocompression bonding, and then the dry film is patterned by photolithography to form the resist layer 100 having the opening pattern 100X. When a liquid photoresist is used, the resist layer 100 may also be formed by the same steps.

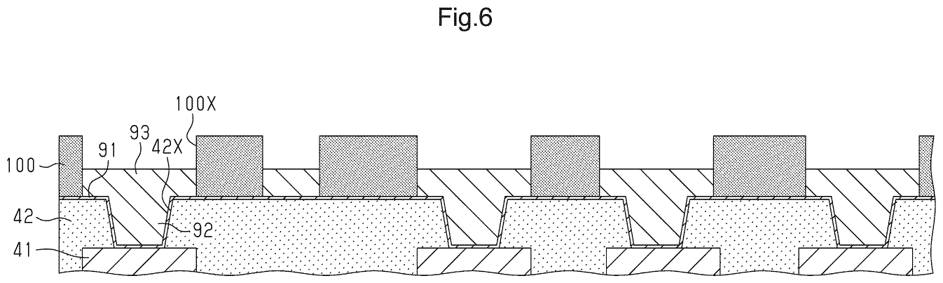

In the step illustrated in FIG. 6, electrolytic plating is performed on the seed layer 91 using the resist layer 100 as a plating mask and the seed layer 91 as a plating power feeding layer. That is, electrolytic plating (here, electrolytic Cu plating) is performed on the upper surface of the seed layer 91 exposed in the opening pattern 100X of the resist layer 100. This step forms a metal layer 92 and a metal layer 93. The metal layer 92 fills the through holes 42X surrounded by the seed layer 91. The metal layer 93 is formed in the opening pattern 100X.

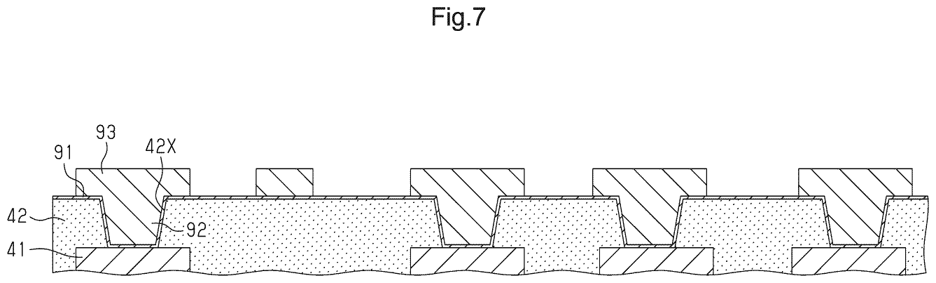

In the step illustrated in FIG. 7, the resist layer 100 illustrated in FIG. 6 is removed using an alkaline stripping solution (e.g., organic amine stripping solution, caustic soda, acetone, ethanol, or the like).

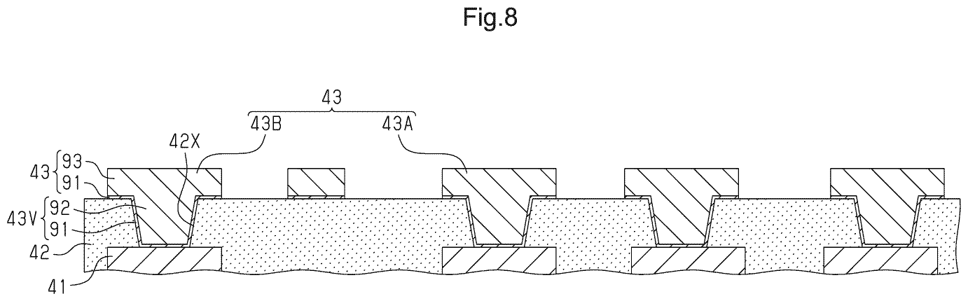

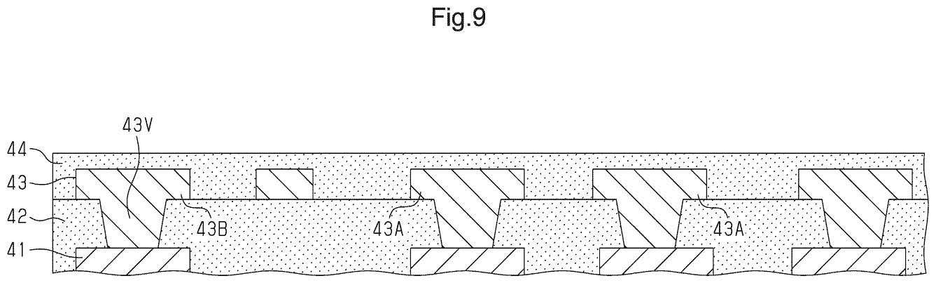

In the step illustrated in FIG. 8, unnecessary parts of the seed layer 91 are removed by etching using the metal layer 93 as an etching mask. This step forms the via wiring 43V and the wiring layer 43. The via wiring 43V includes the seed layer 91 and the metal layer 92, which are formed in the through holes 42X. The via wiring 43V fills the through holes 42X. The wiring layer 43 includes the seed layer 91 and the metal layer 93. The wiring layer 43 is formed on the upper surface of the insulation layer 42. In this case, the wiring layer 43 includes the wiring layer 43A that overlaps the cavity 40X in plan view (refer to FIG. 2), and the wiring layer 43B that does not overlap the cavity 40X in plan view. The cavity 40X is formed in a later step. In FIGS. 9 to 20, the seed layer 91 and the metal layers 92 and 93 are not illustrated, and the via wiring 43V and the wiring layer 43 are illustrated as a single layer.

In the step illustrated in FIG. 9, the insulation layer 44 is formed on the upper surface of the insulation layer 42 and covers the wiring layer 43. The insulation layer 44 covers the entire upper surface and the entire side surface of the wiring layer 43A and also covers the entire upper surface and the entire side surface of the wiring layer 43B. The insulation layer 44 is formed so that the portion of the insulation layer 44 covering the upper surface of the wiring layer 43 is reduced in thickness. For example, the thickness of the portion of the insulation layer 44 covering the upper surface of the wiring layer 43 is approximately 5 μm to 20 μm. For example, after the insulation layer 44 is formed in the same manner as the insulation layer 42, the insulation layer 44 may undergo chemical mechanical polishing (CMP) or ashing (dry etching using oxygen plasma) so that the insulation layer 44 is thinned from the upper surface.

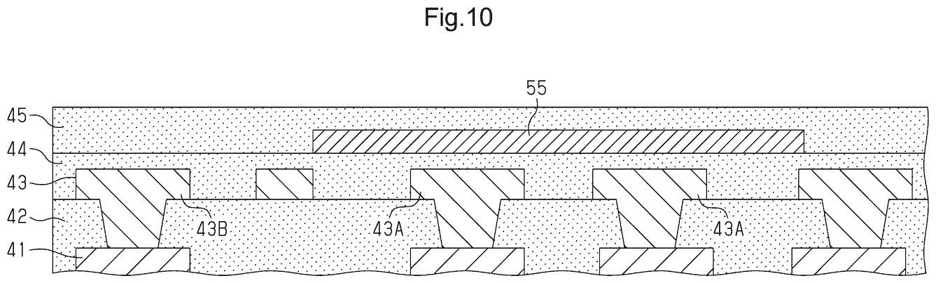

In the step illustrated in FIG. 10, the metal layer 55 is formed on the upper surface of the insulation layer 44. The metal layer 55 overlaps the wiring layer 43A in plan view. The metal layer 55 is arranged in a location that corresponds to a region where the cavity 40X (refer to FIG. 2) is formed in a subsequent step. The metal layer 55 serves as a barrier layer protecting the wiring layer 43A arranged under the insulation layer 44. The material of the metal layer 55 may be, for example, copper or a copper alloy. The material of the metal layer 55 may be a metal differing from the metal forming the wiring layer 43. Examples of such metal include nickel and a nickel alloy.

The insulation layer 45 is formed on the upper surface of the insulation layer 44 to cover the metal layer 55. In this step, the insulation layer 45 covers the entire upper surface and the entire side surface of the metal layer 55.

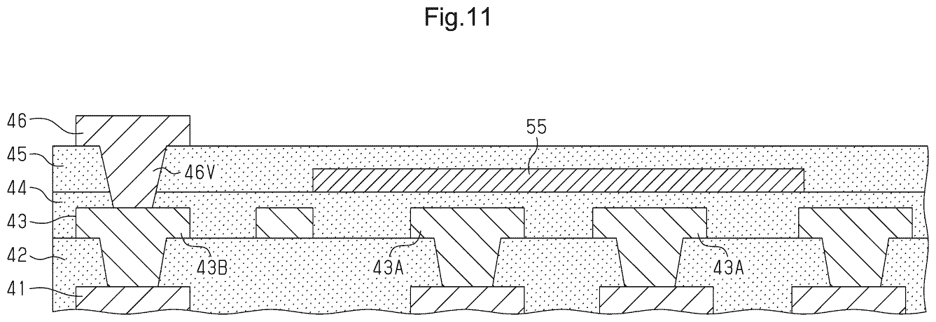

In the step illustrated in FIG. 11, steps similar to those illustrated in FIGS. 5 to 8 are performed to form the wiring layer 46 on the upper surface of the insulation layer 45. The wiring layer 46 is electrically connected to the wiring layer 43B by via wirings 46V extending through the insulation layers 44 and 45 in the thickness-wise direction.

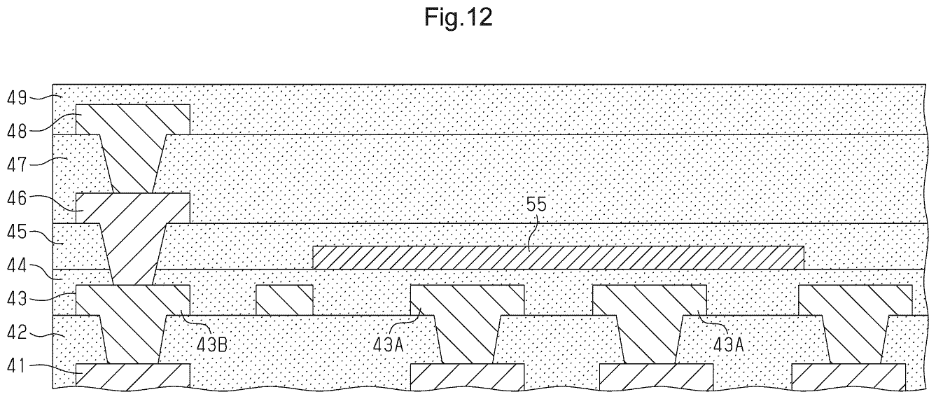

In the step illustrated in FIG. 12, steps similar to those illustrated in FIGS. 4 to 8 are performed to form the insulation layer 47 and the wiring layer 48 on the upper surface of the insulation layer 45. Further, the insulation layer 49 is formed on the upper surface of the insulation layer 47 to cover the wiring layer 48. In this step, the insulation layer 49 covers the entire upper surface and the entire side surface of the wiring layer 48.

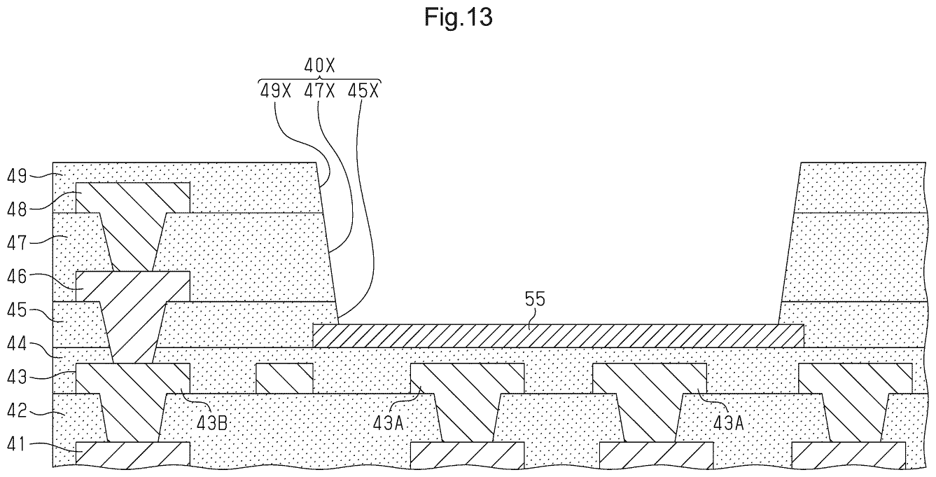

In the step illustrated in FIG. 13, the upper surface of the insulation layer 49 is recessed toward the insulation layer 44 to form the cavity 40X and expose the upper surface of the metal layer 55. For example, the through hole 49X is formed to extend through the insulation layer 49 in the thickness-wise direction. The through hole 47X is formed to be connected to the through hole 49X and extend through the insulation layer 47 in the thickness-wise direction. The through hole 45X is formed to be connected to the through hole 47X and extend through the insulation layer 45 in the thickness-wise direction. That is, the cavity 40X extends through the multiple insulation layers 45, 47, 49 in the thickness-wise direction and exposes part of the upper surface of the metal layer 55. The planar size of the cavity 40X is slightly smaller than the planar size of the metal layer 55. Therefore, the peripheral edge of the metal layer 55 is covered by the insulation layer 45. The through holes 45X, 47X, and 49X may be formed by, for example, laser drilling using CO2 laser, UV-YAG laser, or the like. In this step, the metal layer 55 serves as a stopper layer during laser cutting. This appropriately limits damage to, for example, the insulation layer 44 and the wiring layer 43A arranged under the insulation layer 45.

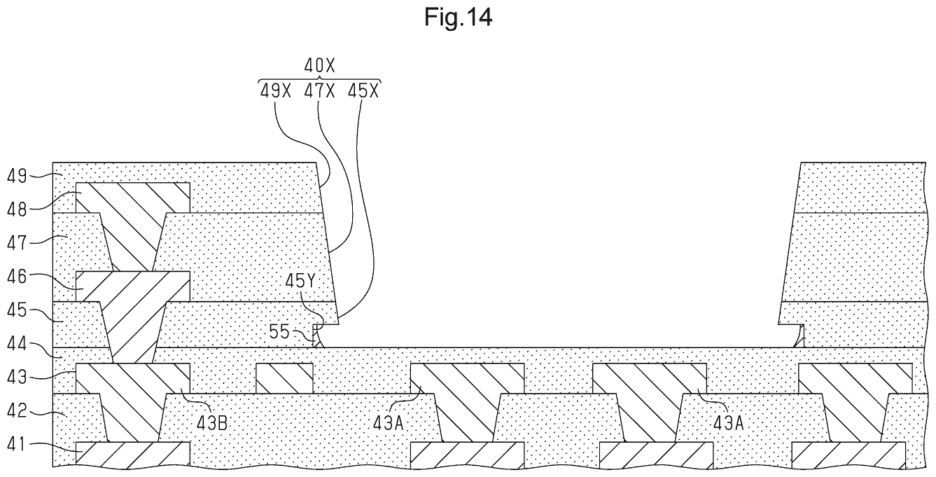

Then, the metal layer 55 is removed by etching. In an example, the metal layer 55 is removed by isotropic etching using the insulation layers 45, 47, and 49 as etching masks. The isotropic etching produces a side etching effect in which etching advances inward in the metal layer 55 in a planar direction. Thus, the metal layer 55 covered by the insulation layer 45 is also removed. As a result, as illustrated in FIG. 14, the recess 45Y is formed at the lower end of the insulation layer 45 defining the wall surface of the through hole 45X. The metal layer 55 covered by the insulation layer 45 may be completely removed or the metal layer 55 covered by the insulation layer 45 may partially remain, as illustrated in FIG. 14, depending on the condition of the etching process used in this step.

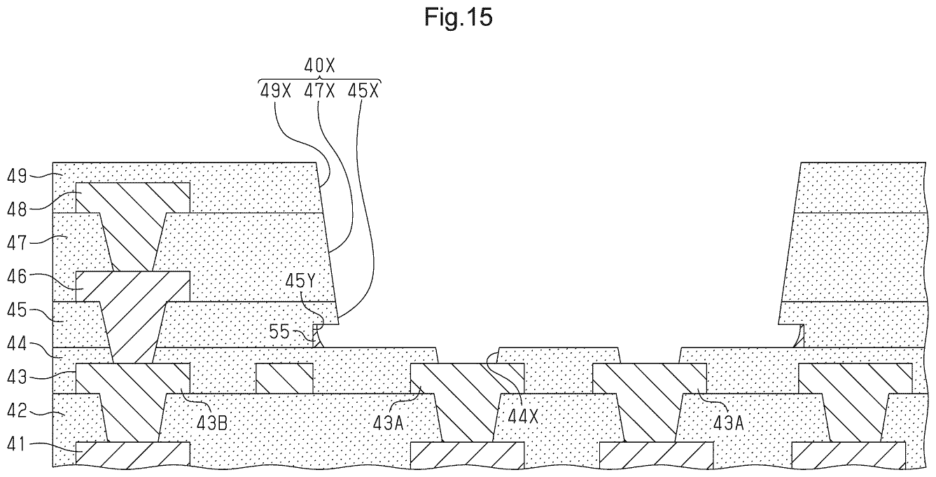

In the step illustrated in FIG. 15, the openings 44X are formed in the upper surface of the insulation layer 44 at given locations exposed at the bottom of the cavity 40X so that the upper surface of the wiring layer 43A is partially exposed. The openings 44X extend through the insulation layer 44 in the thickness-wise direction and expose parts of the upper surface of the wiring layer 43A. The openings 44X may be formed by, for example, laser drilling using CO₂ laser, UV-YAG laser, or the like.

When the openings 44X are formed by laser cutting, a desmear process is performed to remove resin smears from the surface of the wiring layer 43A exposed at the bottom of the openings 44X. The desmear process in this step may be, for example, a wet desmear process using a potassium permanganate solution or the like.

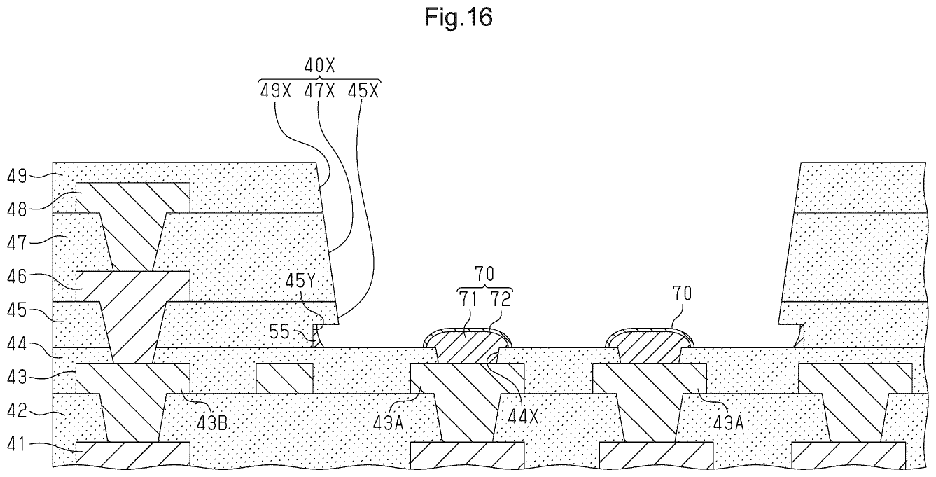

In the step illustrated in FIG. 16, the connection terminals 70 are formed on the parts of the upper surface of the wiring layer 43A exposed from the openings 44X. The connection terminals 70 fill the openings 44X and project upward from the upper surface of the insulation layer 44. The connection terminals 70 may be formed, for example, by electroless plating. For example, electroless plating (in this embodiment, electroless Ni plating) is performed to form the first metal layer 71 (Ni layer) that fills the openings 44X and project upward from the upper surface of the insulation layer 44. Then, electroless plating (in this embodiment, electroless Au plating) is performed to form the second metal layer 72 (Au layer) that covers the entire surface of the first metal layer 71 exposed from the insulation layer 44.

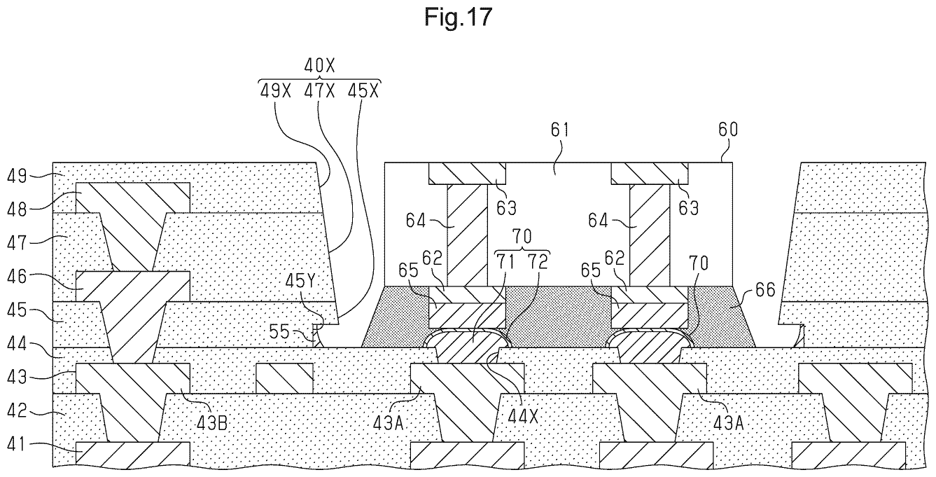

In the step illustrated in FIG. 17, the electronic component 60 is prepared including the main body 61, the first electrode 62, the second electrode 63, and the through-electrode 64. The electronic component 60 is mounted on the connection terminals 70 in the cavity 40X. For example, the first electrodes 62 of the electronic component 60 are bonded to the connection terminals 70 formed on the surface of the wiring layer 43A by the bonding members 65. In an example in which the bonding members 65 are a solder layer, flux (not illustrated) is applied to the connection terminals 70, and then the first electrodes 62 are positioned relative to the connection terminals 70 in a state in which the bonding members 65 are arranged between the first electrodes 62 and the connection terminals 70. Subsequently, a reflow process is performed at a temperature of approximately 230° C. to 260° C. This melts the solder layer serving as the bonding members 65, so that the bonding members 65 electrically connect the connection terminals 70 and the first electrodes 62. Subsequently, the gap between the bottom surface of the cavity 40X and the lower surface of the main body 61 of the electronic component 60 is filled with the underfill resin 66, and then the underfill resin 66 is cured. The underfill resin 66 may be applied in advance to the lower surface of the main body 61 of the electronic component 60. Then, when mounting the electronic component 60, the underfill resin 66 may fill the cavity 40X to the bottom surface.

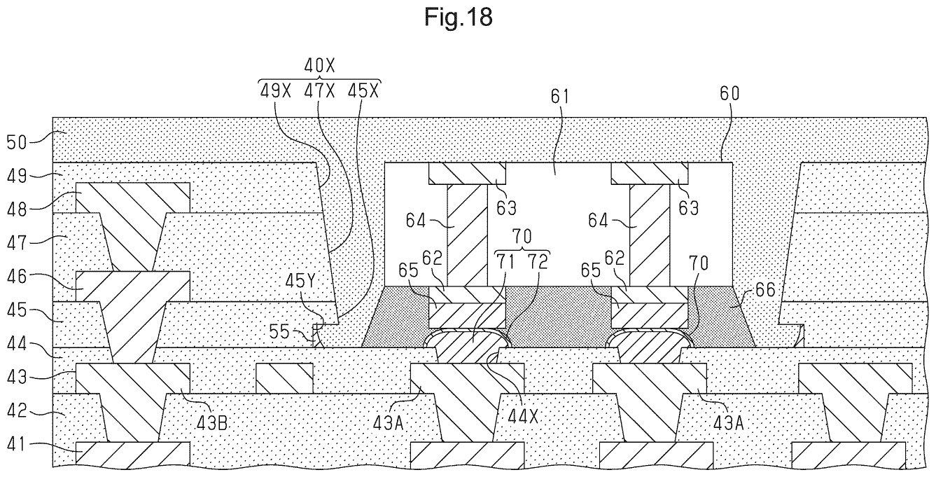

In the step illustrated in FIG. 18, a step similar to that illustrated in FIG. 4 is performed to form the insulation layer 50 that covers the upper surface of the insulation layer 49 and fills the cavity 40X. The insulation layer 50 covers the entire side surface of the underfill resin 66 and the entire surface of the electronic component 60 exposed from the underfill resin 66. The insulation layer 50 fills the recess 45Y. In this step, the side surface and the upper surface of the wiring layer 43A are covered by the insulation layer 44. Thus, the depth of the cavity 40X is decreased as compared to a structure in which the side surface and the upper surface of the wiring layer 43A are exposed from the insulation layer 44. Accordingly, the volume of the cavity 40X is decreased. This improves the filling factor of the cavity 40X with the insulation layer 50. As a result, formation of voids (air bubbles) in the insulation layer 50 is appropriately limited.

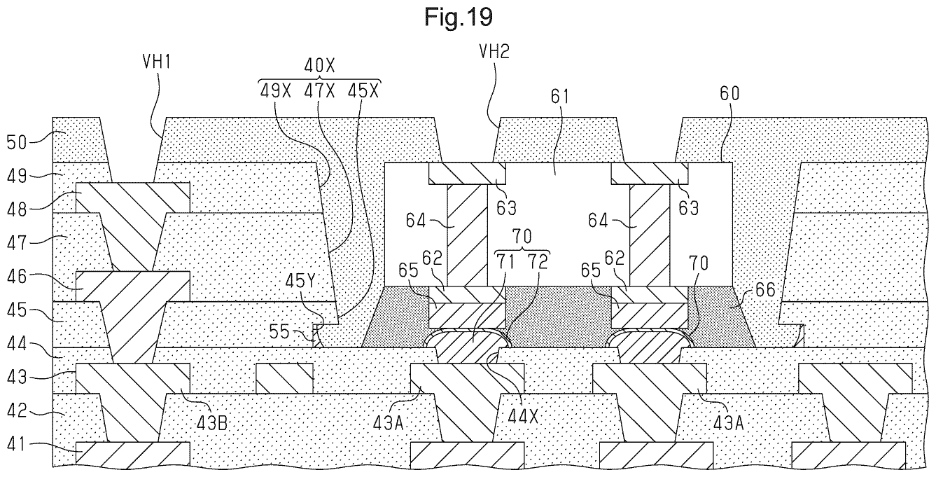

In the step illustrated in FIG. 19, a step similar to that illustrated in FIG. 4 is performed to form the through holes VH1 at given locations of the insulation layers 49 and 50. The through holes VH1 extend through the insulation layers 49 and 50 in the thickness-wise direction and expose parts of the upper surface of the wiring layer 48. Also, the through holes VH2 are formed at given locations of the insulation layer 50. The through holes VH2 extend through the insulation layer 50 in the thickness-wise direction and expose parts of the upper surface of the second electrode 63.

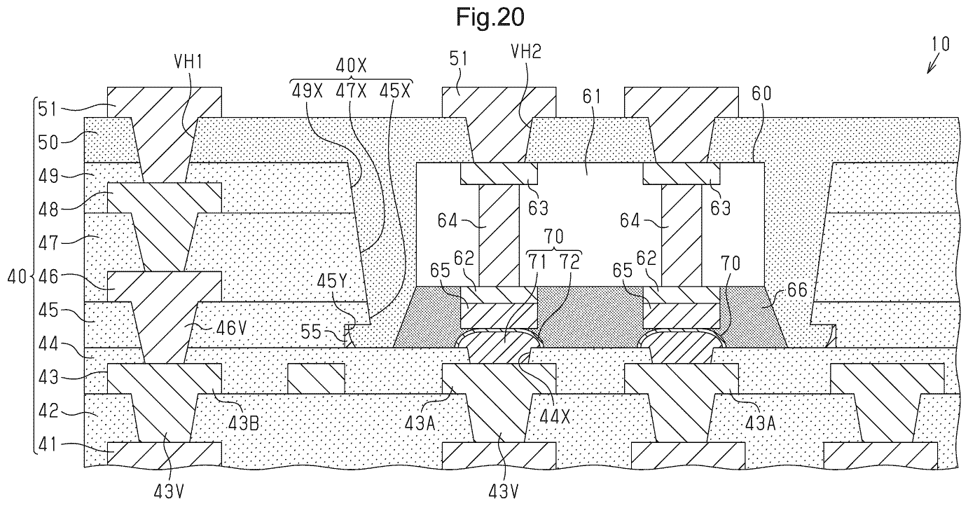

In the step illustrated in FIG. 20, steps similar to those illustrated in FIGS. 5 to 8 are performed to form via wiring filling the through holes VH1, and form the wiring layer 51 on the upper surface of the insulation layer 50. In this manner, the wiring layer 51 is electrically connected to the wiring layer 48 by the via wiring. Also, via wiring is formed to fill the through holes VH2, and the wiring layer 51 is formed on the upper surface of the insulation layer 50. In this manner, the wiring layer 51 is electrically connected to the second electrodes 63 by the via wiring.

The manufacturing steps described above manufacture the structural body illustrated in FIG. 2. Thereafter, the insulation layer 52, the wiring layer 53, and the like illustrated in FIG. 1 are formed to manufacture the wiring substrate 10 of the present embodiment.

In the present embodiment, the insulation layer 42 is an example of a first insulation layer. The wiring layer 43A is an example of a first wiring layer. The wiring layer 43B is an example of a second wiring layer. The insulation layer 44 is an example of a second insulation layer. The upper surface of the insulation layer 44 is an example of a first surface. The insulation layers 45, 47, and 49 are an example of N number of insulation layers. The insulation layer 50 is an example of a capping insulation layer. The wiring layer 51 is an example of a third wiring layer. The insulation layer 45 is an example of a third insulation layer. The wiring layer 46 is an example of a fourth wiring layer. The recess 45Y is an example of a first recess.

### Operation and Advantages of the First Embodiment

The present embodiment has the advantages described below.

(1-1) The wiring substrate 10 includes the insulation layer 42, the wiring layers 43A and 43B formed on the upper surface of the insulation layer 42, and the insulation layer 44 formed on the upper surface of the insulation layer 42 to cover the side surface and the upper surface of the wiring layer 43A and the side surface and the upper surface of the wiring layer 43B. The wiring substrate 10 includes N number of (in this embodiment, three) insulation layers 45, 47, and 49 formed on the upper surface of the insulation layer 44, and the cavity 40X formed in the three insulation layers 45, 47, and 49 and exposing the upper surface of the insulation layer 44. The wiring substrate 10 includes the opening 44X formed in the upper surface of the insulation layer 44 exposed from the cavity 40X and extending through the insulation layer 44 in the thickness-wise direction to expose part of the upper surface of the wiring layer 43A, and the connection terminal 70 formed on the upper surface of the wiring layer 43A exposed from the opening 44X. The wiring substrate 10 includes the electronic component 60 arranged in the cavity 40X and mounted on the connection terminal 70, and the insulation layer 50 filling the cavity 40X and covering the electronic component 60. The wiring substrate 10 includes the wiring layer 51 mounted on the upper surface of the insulation layer 50 and electrically connected to the electronic component 60. The wiring layer 43A overlaps the cavity 40X in plan view. The wiring layer 43B does not overlap the cavity 40X in plan view.

With this structure, the side surface and the upper surface of the wiring layer 43A are covered by the insulation layer 44 at the bottom of the cavity 40X. Thus, the depth of the cavity 40X is decreased as compared to a structure in which the cavity 40X is formed so that the side surface and the upper surface of the wiring layer 43A are exposed from the insulation layer 44. Accordingly, the volume of the cavity 40X is decreased. This improves the filling factor of the cavity 40X with the insulation layer 50. As a result, formation of voids in the insulation layer 50 is appropriately limited. The improvement in the filling factor of the cavity 40X with the insulation layer 50 improves the flatness of the upper surface of the insulation layer 50.

(1-2) The insulation layer 44 covers the side surface and the upper surface of the wiring layer 43B, which does not overlap the cavity 40X in plan view, and also covers the side surface and the upper surface of the wiring layer 43A, which overlaps the cavity 40X in plan view. Thus, the structure of the wiring substrate 10 is simplified as compared to a structure in which the side surface and the upper surface of the wiring layer 43A are covered by an insulation layer that differs from an insulation layer that covers the side surface and the upper surface of the wiring layer 43B. This, for example, reduces steps for manufacturing the wiring substrate 10.

(1-3) The method for manufacturing the wiring substrate 10 includes forming the wiring layers 43A and 43B on the upper surface of the insulation layer 42 and forming the insulation layer 44 on the upper surface of the insulation layer 42 to cover the side surface and the upper surface of the wiring layers 43A and 43B. The method for manufacturing the wiring substrate 10 includes forming the metal layer 55 on the upper surface of the insulation layer 44 so that the metal layer 55 overlaps the wiring layer 43A in plan view, forming N number of (in this embodiment, three) insulation layers 45, 47, 49 on the upper surface of the insulation layer 44 to cover the metal layer 55. The method for manufacturing the wiring substrate 10 includes forming the cavity 40X in the three insulation layers 45, 47, and 49 through laser cutting so that the cavity 40X exposes the upper surface of the metal layer 55, and removing the metal layer 55. The method for manufacturing the wiring substrate 10 includes forming the opening 44X in the upper surface of the insulation layer 44 exposed at the bottom of the cavity 40X so that the opening 44X extends through the insulation layer 44 in the thickness-wise direction and exposes part of the upper surface of the wiring layer 43A. The method for manufacturing the wiring substrate 10 includes forming the connection terminal 70 on the upper surface of the wiring layer 43A exposed from the opening 44X and mounting the electronic component 60 on the connection terminal 70 in the cavity 40X. The method for manufacturing the wiring substrate 10 includes forming the insulation layer 50 filling the cavity 40X and covering the electronic component 60 and forming the wiring layer 51 on the upper surface of the insulation layer 50.

In this structure, the metal layer 55 is formed as a barrier layer on the upper surface of the insulation layer 44, which covers the side surface and the upper surface of the wiring layer 43A. Thus, the metal layer 55 is not in direct contact with the side surface and the upper surface of the wiring layer 43A. This simplifies the step for forming the metal layer 55 and the step for removing the metal layer 55 as compared to a structure in which a barrier layer is formed to directly contact the side surface and the upper surface of the wiring layer 43A. In the step of removing the metal layer 55, the side surface and the upper surface of the wiring layer 43A are covered by the insulation layer 44. Therefore, when the metal layer 55 is removed by etching or the like, partial etching of the side surface and the upper surface of the wiring layer 43A is avoided in a preferred manner.

(1-4) The wiring substrate 10 includes the wiring layer 46 formed on the upper surface of the insulation layer 45 and electrically connected to the wiring layer 43B by the via wiring 46V extending through the insulation layer 44 and the insulation layer 45 in the thickness-wise direction. In this structure, two layers, namely, the insulation layers 44 and 45, are arranged between the wiring layer 43B and the wiring layer 46. Thus, even when the wiring layer 43B and the wiring layer 46 need to be separated by a given thickness, the parts of the insulation layer 44 covering the upper surfaces of the wiring layers 43A and 43B have a smaller thickness than that in a structure in which only a single layer, that is, the insulation layer 44, is arranged between the wiring layer 43B and the wiring layer 46. This decreases the thickness from the upper surfaces of the wiring layers 43A and 43B to the upper surface of the insulation layer 44, thereby decreasing the depth of the openings 44X. As a result, for example, the connection terminal 70 formed in the opening 44X readily projects upward from the upper surface of the insulation layer 44.

### Second Embodiment

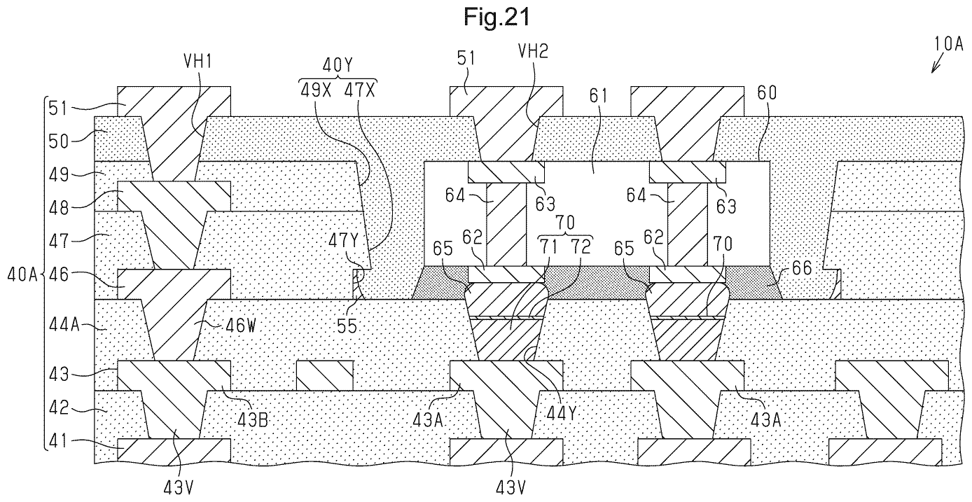

A second embodiment will now be described with reference to FIGS. 21 to 31. The differences from the first embodiment will be mainly discussed. The same reference numerals are given to those components that are the same as the corresponding components illustrated in FIGS. 1 to 20. Such components will not be described in detail.

As illustrated in FIG. 21, the wiring substrate 10A has a wiring structure 40A obtained by sequentially stacking a wiring layer 41, an insulation layer 42, a wiring layer 43, an insulation layer 44A, a wiring layer 46, an insulation layer 47, a wiring layer 48, an insulation layer 49, an insulation layer 50, and a wiring layer 51. The wiring structure 40A includes a cavity 40Y accommodating the electronic component 60.

The insulation layer 44A is formed on the upper surface of the insulation layer 42 to cover the wiring layer 43. The insulation layer 44A covers the upper surface and side surface of the wiring layer 43A, which overlaps the cavity 40Y in plan view, and also covers the upper surface and side surface of the wiring layer 43B, which does not overlap the cavity 40Y in plan view. The insulation layer 44A has, for example, a greater thickness than the insulation layer 44 in the first embodiment. The thickness from the upper surface of the wiring layer 43 to the upper surface of the insulation layer 44A is, for example, greater than the thickness from the upper surface of the wiring layer 43 to the upper surface of the insulation layer 44 that is illustrated in FIG. 2. The thickness from the upper surface of the wiring layer 43 to the upper surface of the insulation layer 44A may be, for example, approximately 20 μm to 60 μm.

The wiring layer 46 is formed on the upper surface of the insulation layer 44A. The wiring layer 46 is electrically connected to the wiring layer 43B by via wiring 46W extending through the insulation layer 44A in the thickness-wise direction. The wiring layer 46 does not overlap the cavity 40Y in plan view. The insulation layer 47 is formed on the upper surface of the insulation layer 44A to cover the wiring layer 46.

The cavity 40Y is formed in the insulation layers 47 and 49. The cavity 40Y is recessed downward from the upper surface of the insulation layer 49. The cavity 40Y extends through the insulation layers 47 and 49 in the thickness-wise direction.

The cavity 40Y of the present embodiment includes a through hole 49X extending through the insulation layer 49 in the thickness-wise direction, and a through hole 47X extending through the insulation layer 47 in the thickness-wise direction. The through hole 49X is continuous with the through hole 47X. The cavity 40Y exposes, for example, part of the upper surface of the insulation layer 44A. In other words, the bottom surface of the cavity 40Y is defined by the upper surface of the insulation layer 44A. The depth of the cavity 40Y, that is, the thickness from the upper surface of the insulation layer 44A to the upper surface of the insulation layer 49, may be, for example, approximately 60 μm to 150 μm.

The cavity 40Y is, for example, tapered so that the width decreases from the upper side (upper surface of insulation layer 49) toward the lower side (insulation layer 44A), as viewed in FIG. 21. That is, the cavity 40Y widens from the lower side toward the upper side.

As described above, in the wiring substrate 10A of the present embodiment, the two insulation layers 47 and 49 formed on the insulation layer 44A serve as insulation layers in which the cavity is formed.

A recess 47Y is formed in a lower end of the insulation layer 47, which forms a wall surface of the cavity 40Y. For example, of the wall surfaces of the cavity 40Y, a wall surface that is in contact with the insulation layer 44A is recessed into the insulation layer 47, which forms the recess 47Y. The recess 47Y is continuous with the cavity 40Y. Thus, the recess 47Y is formed at the bottom of the cavity 40Y to widen the cavity 40Y.

The recess 47Y is formed, for example, along the entire perimeter of the cavity 40Y. Alternatively, the recess 47Y may be formed in part of the perimeter of the cavity 40Y. The dimension of the recess 47Y in the thickness-wise direction (vertical direction in FIG. 21) of the insulation layer 47, that is, the depth of the recess 47Y, is set to be, for example, approximately the same as the thickness of the wiring layer 46. The depth of the recess 47Y may be, for example, approximately 5 μm to 35 μm.

In an example, the metal layer 55 is formed in the recess 47Y. The metal layer 55 is in contact with the upper surface of the insulation layer 44A. The metal layer 55 is in contact with an inner wall surface of the recess 47Y. When the metal layer 55 is formed, the recess 47Y is defined by a space surrounded by the metal layer 55, the lower surface of the insulation layer 47 exposed from the metal layer 55, and the upper surface of the insulation layer 44A exposed from the metal layer 55.

Openings 44Y are formed in the upper surface of the insulation layer 44A exposed from the cavity 40Y. The openings 44Y extend through the insulation layer 44A in the thickness-wise direction to expose parts of the upper surface of the wiring layer 43A. The openings 44Y have a thickness that is, for example, greater than that of the openings 44X in the first embodiment. Each opening 44Y is, for example, tapered so that the width decreases from the upper side (upper surface of insulation layer 44A) toward the lower side (wiring layer 43A), as viewed in FIG. 21.

Connection terminals 70 are formed on the parts of the upper surface of the wiring layer 43A exposed from the openings 44Y. In the present embodiment, the connection terminals 70 have a structure in which a first metal layer 71 and a second metal layer 72 are stacked.

The first metal layer 71 covers the entire upper surface of the wiring layer 43A exposed from the openings 44Y. In an example, the first metal layer 71 fills lower portions of the openings 44Y. The upper surface of the first metal layer 71 is located, for example, at a position recessed downward from the upper surface of the insulation layer 44A. The upper surface of the first metal layer 71 is, for example, horizontally flat in the planar direction. The second metal layer 72 covers the entire upper surface of the first metal layer 71. The second metal layer 72 is, for example, arranged in the openings 44Y.

The electronic component 60 is, for example, flip-chip mounted on the wiring layer 43A exposed in the cavity 40Y and the openings 44Y. For example, the first electrodes 62 of the electronic component 60 are electrically connected to the connection terminals 70 formed on the parts of the upper surface of the wiring layer 43A exposed in the openings 44Y. For example, the first electrodes 62 are electrically connected to the connection terminals 70 by bonding members 65. Thus, the electronic component 60 is electrically connected to the wiring layer 43A by the first electrodes 62, the bonding members 65, and the connection terminals 70. The bonding members 65, for example, fill the openings 44Y exposed from the connection terminals 70.

The underfill resin 66 fills the gap between the lower surface of the main body 61 of the electronic component 60 and the bottom surface of the cavity 40Y, in this embodiment, the upper surface of the insulation layer 44A. The underfill resin 66 encapsulates, for example, the first electrodes 62 and the bonding members 65.

The insulation layer 50 fills both the cavity 40Y and the recess 47Y. The insulation layer 50 covers the entire upper surface of the insulation layer 49.

Although not illustrated, in the same manner as the wiring substrate 10 illustrated in FIG. 1, the insulation layer 52 and the wiring layer 53 are sequentially stacked on the upper surface of the insulation layer 50 of the wiring substrate 10A, and the external connection terminals 90 are formed on the upper surface of the wiring layer 53.

### Method for Manufacturing the Wiring Substrate 10A

A method for manufacturing the wiring substrate 10A will now be described. To facilitate understanding, portions that ultimately become elements of the wiring substrate 10A are indicated by reference characters used to denote the final elements.

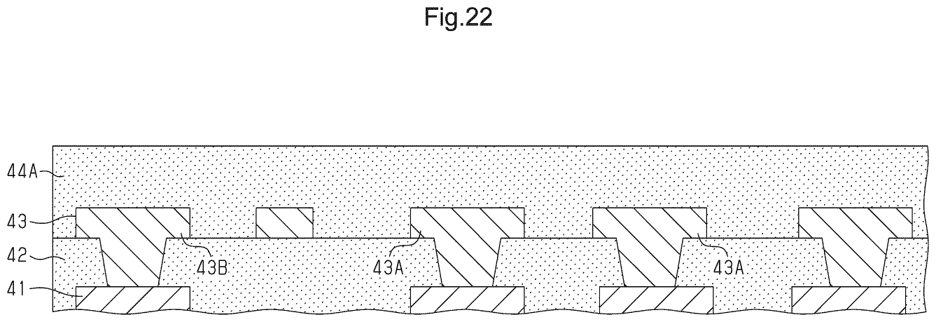

In the step illustrated in FIG. 22, steps similar to those illustrated in FIGS. 4 to 8 are performed to form the wiring layer 43 on the upper surface of the insulation layer 42. Then, the insulation layer 44A is formed on the upper surface of the insulation layer 42 to cover the wiring layer 43. The insulation layer 44A has, for example, a greater thickness than the insulation layer 44 illustrated in FIG. 9.

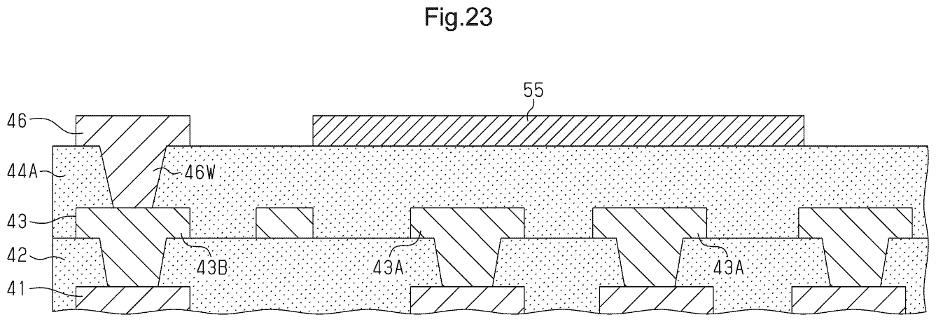

In the step illustrated in FIG. 23, steps similar to those illustrated in FIGS. 5 to 8 are performed to form the wiring layer 46 and the metal layer 55 on the upper surface of the insulation layer 44A. In an example, the wiring layer 46 and the metal layer 55 are simultaneously formed in the same step. The wiring layer 46 is electrically connected to the wiring layer 43A by the via wiring 46W extending through the insulation layer 44A in the thickness-wise direction. The metal layer 55 overlaps the wiring layer 43A in plan view. The metal layer 55 is arranged in a location that corresponds to a region where the cavity 40Y (refer to FIG. 21) is formed in a subsequent step. The metal layer 55 serves as a barrier layer protecting the wiring layer 43A arranged under the insulation layer 44A.

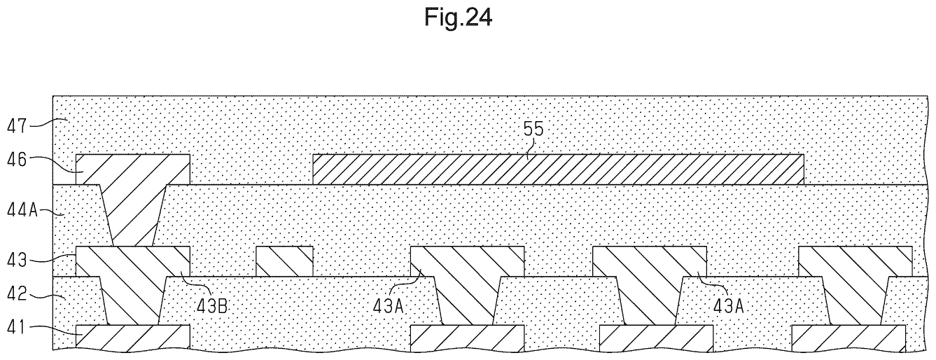

In the step illustrated in FIG. 24, the insulation layer 47 is formed on the upper surface of the insulation layer 44A to cover the wiring layer 46 and the metal layer 55.

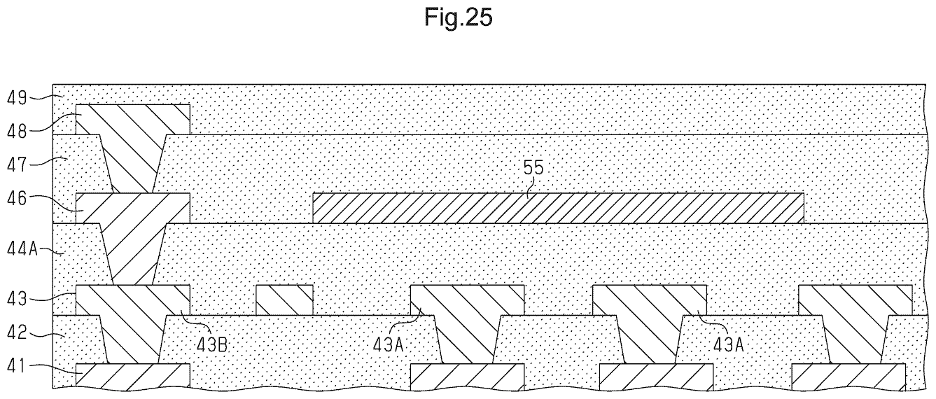

In the step illustrated in FIG. 25, the wiring layer 48 and the insulation layer 49 are formed on the upper surface of the insulation layer 47. In this step, the insulation layer 49 covers the entire upper surface and the entire side surface of the wiring layer 48.

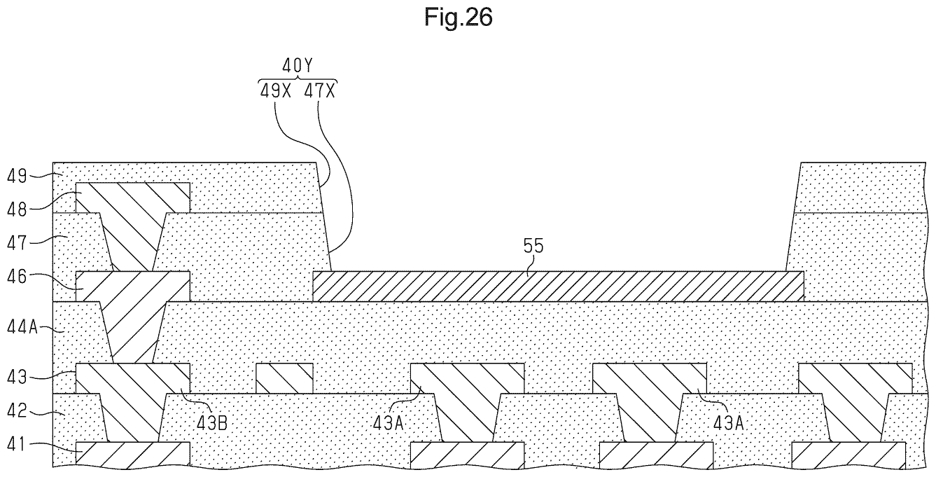

In the step illustrated in FIG. 26, a step similar to that illustrated in FIG. 13 is performed to form the cavity 40Y recessed from the upper surface of the insulation layer 49 toward the insulation layer 44A to expose the upper surface of the metal layer 55. In an example, the through hole 49X is formed to extend through the insulation layer 49 in the thickness-wise direction. The through hole 47X is formed to be connected to the through hole 49X and extend through the insulation layer 47 in the thickness-wise direction. That is, the cavity 40Y extends through the multiple insulation layers 47 and 49 in the thickness-wise direction and exposes part of the upper surface of the metal layer 55. The planar size of the cavity 40Y is slightly smaller than the planar size of the metal layer 55. Therefore, the peripheral edge of the metal layer 55 is covered by the insulation layer 47. In this step, the metal layer 55 serves as a stopper layer during laser cutting.

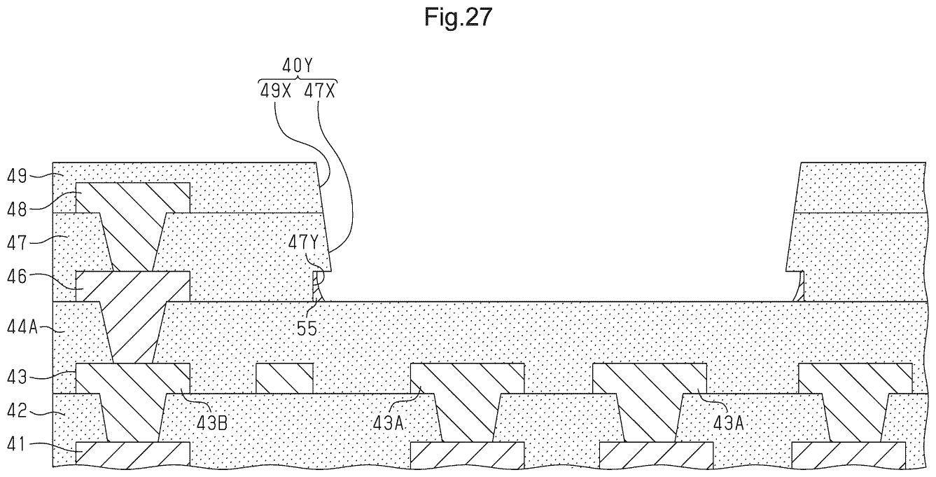

In the step illustrated in FIG. 27, a step similar to that illustrated in FIG. 14 is performed to remove the metal layer 55 by etching. In this step, the recess 47Y is formed at the lower end of the insulation layer 47 defining the wall surface of the through hole 47X.

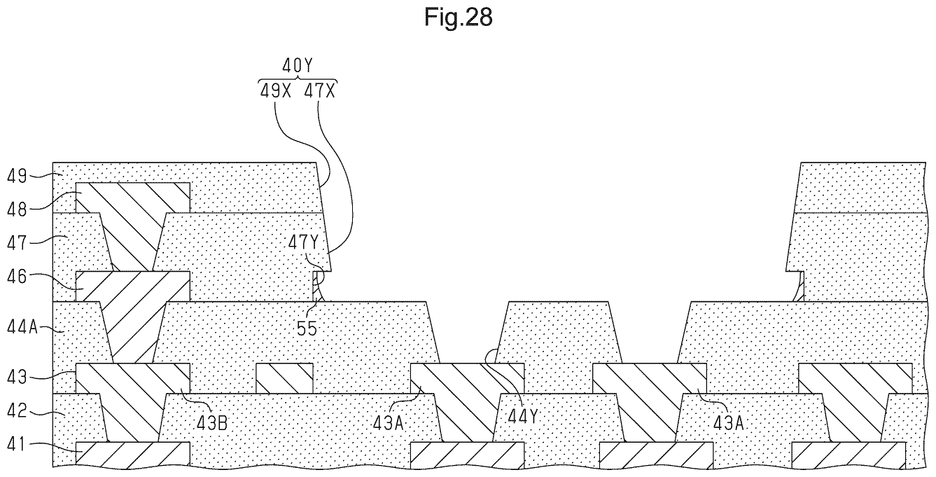

In the step illustrated in FIG. 28, a step similar to that illustrated in FIG. 15 is performed to form the openings 44Y in the upper surface of the insulation layer 44A exposed at the bottom of the cavity 40Y to expose parts of the upper surface of the wiring layer 43A.

When the openings 44Y are formed by laser cutting, a desmear process is performed to remove resin smears from the surface of the wiring layer 43A exposed at the bottom of the openings 44Y.

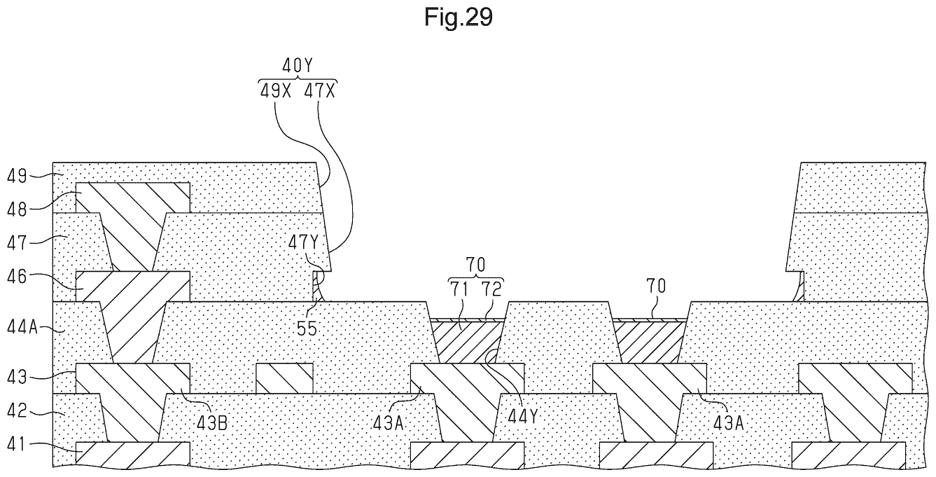

In the step illustrated in FIG. 29, a step similar to that illustrated in FIG. 16 is performed to form the connection terminals 70 on the upper surface of the wiring layer 43A exposed from the openings 44Y. The connection terminals 70 fill lower portions of the openings 44Y.

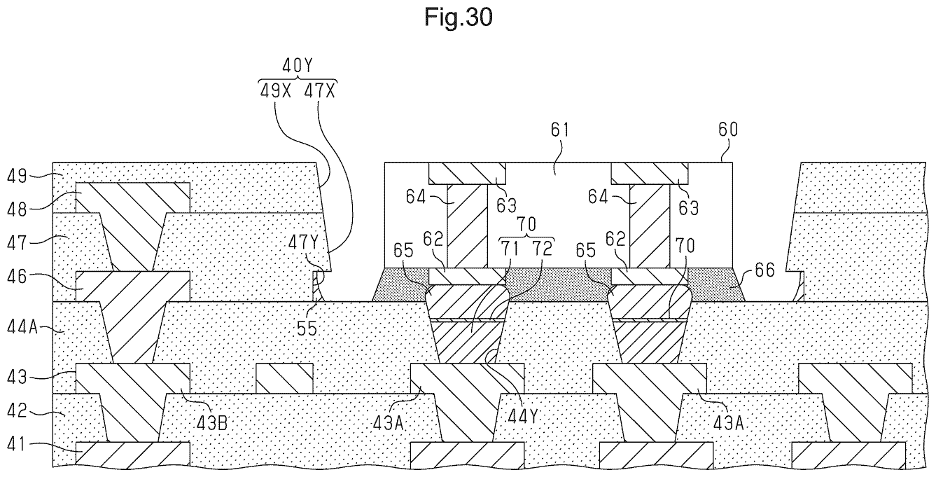

In the step illustrated in FIG. 30, a step similar to that illustrated in FIG. 17 is performed to mount the electronic component 60 on the connection terminals 70 in the cavity 40Y. Subsequently, the gap between the bottom surface of the cavity 40Y and the lower surface of the main body 61 of the electronic component 60 is filled with the underfill resin 66, and then the underfill resin 66 is cured. The underfill resin 66 may be applied in advance to the lower surface of the main body 61 of the electronic component 60. Then, when mounting the electronic component 60, the underfill resin 66 may fill the cavity 40Y to the bottom surface.

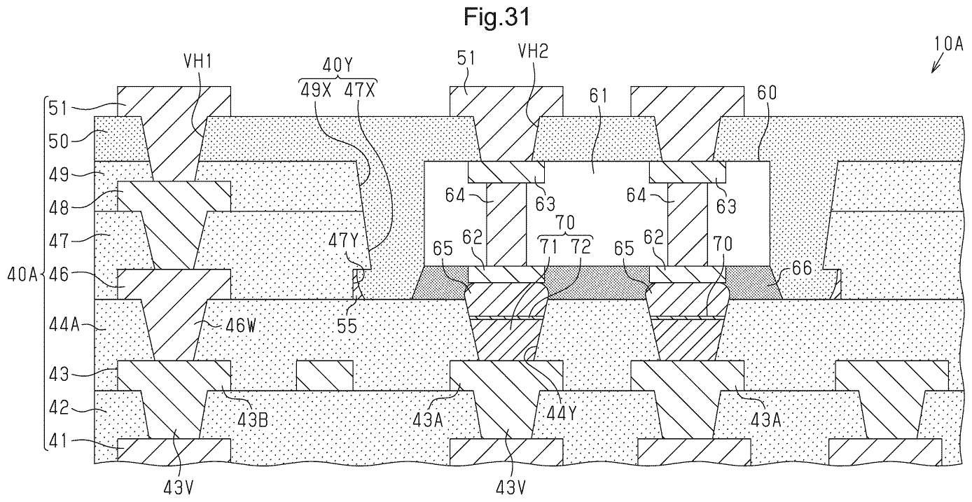

In the step illustrated in FIG. 31, steps similar to those illustrated in FIGS. 18 to 20 are performed to form the insulation layer 50 filling the cavity 40Y and form the wiring layer 51 on the upper surface of the insulation layer 50.

The manufacturing steps described above manufacture the structural body illustrated in FIG. 21.

In the present embodiment, the insulation layer 42 is an example of a first insulation layer. The wiring layer 43A is an example of a first wiring layer. The wiring layer 43B is an example of a second wiring layer. The insulation layer 44A is an example of a second insulation layer. The upper surface of the insulation layer 44A is an example of a first surface. The insulation layers 47 and 49 are an example of N number of insulation layers.

The insulation layer 47 is an example of a fourth insulation layer. The insulation layer 50 is an example of a capping insulation layer. The wiring layer 51 is an example of a third wiring layer. The wiring layer 46 is an example of a fourth wiring layer. The recess 47Y is an example of a third recess.

### Operation and Advantages of the Second Embodiment

In addition to the operation and advantages (1-1) to (1-3) of the first embodiment, the present embodiment has the operation and advantages described below.

(2-1) The wiring substrate 10A includes the wiring layer 46 formed on the upper surface of the insulation layer 44A and electrically connected to the wiring layer 43B by the via wiring 46W extending through the insulation layer 44A in the thickness-wise direction.

### The insulation layer 47 covers the wiring layer 46.

In this structure, a single layer, namely, the insulation layer 44A, is arranged between the wiring layer 43B and the wiring layer 46. Thus, the structure of the wiring substrate 10A is simplified as compared to a structure in which multiple insulation layers are arranged between the wiring layer 43B and the wiring layer 46. As a result, for example, steps for manufacturing the wiring substrate 10A are reduced.

### Third Embodiment

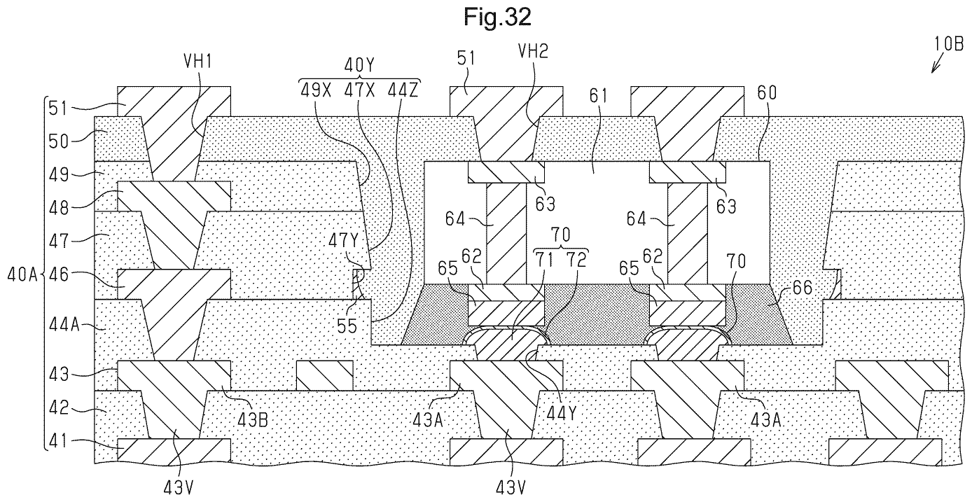

A third embodiment will now be described with reference to FIGS. 32 to 38. The description hereafter will focus on differences from the second embodiment. The same reference numerals are given to those components that are the same as the corresponding components illustrated in FIGS. 1 to 31. Such components will not be described in detail.

As illustrated in FIG. 32, a wiring substrate 10B has a wiring structure 40A including the cavity 40Y accommodating the electronic component 60. In the present embodiment, the cavity 40Y is recessed from the upper surface of the insulation layer 49 to an intermediate part of the insulation layer 44A in the thickness-wise direction. The cavity 40Y of the present embodiment includes a through hole 49X extending through the insulation layer 49 in the thickness-wise direction, a through hole 47X extending through the insulation layer 47 in the thickness-wise direction, and a recess 44Z formed in the upper surface of the insulation layer 44. The through hole 49X, the through hole 47X, and the recess 44Z are continuous with one another. In an example, the wall surface of the recess 44Z extends orthogonal to the upper surface of the insulation layer 44A. Alternatively, the wall surface of the recess 44Z may include an inclined surface that is inclined toward the planar center of the recess 44Z as the wall surface extends toward the bottom surface of the recess 44Z. The bottom surface of the recess 44Z, that is, the bottom surface of the cavity 40Y, is located at an intermediate part of the insulation layer 44A in the thickness-wise direction. The bottom surface of the cavity 40Y is located above the upper surface of the wiring layer 43A and below the lower surface of the wiring layer 46.

As described above, in the wiring substrate 10B of the present embodiment, the three insulation layers 44A, 47, and 49 stacked on the insulation layer 42, which is the lowermost layer of the wiring structure 40A, serve as insulation layers in which the cavity is formed.

In the present embodiment, the recess 47Y is arranged at an intermediate position of the wall surface of the cavity 40Y. The recess 47Y is arranged above the recess 44Z. In other words, the recess 44Z is recessed downward from the recess 47Y. In an example, the metal layer 55 is formed in the recess 47Y.

The openings 44Y are formed at the bottom surface of the recess 44Z to extend through the insulation layer 44A in the thickness-wise direction and expose parts of the upper surface of the wiring layer 43A. The openings 44Y each have a depth that is, for example, smaller than that of the openings 44Y of the second embodiment by the depth of the recess 44Z. Each opening 44Y is, for example, tapered so that the width decreases from the upper side (bottom surface of the recess 44Z) toward the lower side (wiring layer 43A) as viewed in FIG. 32.

Connection terminals 70 are formed on the parts of the upper surface of the wiring layer 43A exposed from the openings 44Y. In an example, the first metal layer 71 fills the openings 44Y. In an example, the first metal layer 71 projects upward from the bottom surface of the recess 44Z. The second metal layer 72 covers the entire surface of the first metal layer 71.

The electronic component 60 is, for example, flip-chip mounted on the wiring layer 43A exposed in the cavity 40Y and the openings 44Y. The underfill resin 66 fills the gap between the lower surface of the main body 61 of the electronic component 60 and the bottom surface of the cavity 40Y, in this embodiment, the bottom surface of the recess 44Z.

The insulation layer 50 fills both the cavity 40Y and the recess 47Y. The insulation layer 50 fills both the through holes 47X and 49X and the recess 44Z. The insulation layer 50 covers the entire upper surface of the insulation layer 49.

Although not illustrated, in the same manner as the wiring substrate 10 illustrated in FIG. 1, the insulation layer 52 and the wiring layer 53 are sequentially stacked on the upper surface of the insulation layer 50 of the wiring substrate 10B, and the external connection terminals 90 are formed on the upper surface of the wiring layer 53.

### Method for Manufacturing the Wiring Substrate 10B

A method for manufacturing the wiring substrate 10B will now be described. To facilitate understanding, portions that ultimately become elements of the wiring substrate 10B are indicated by reference characters used to denote the final elements.

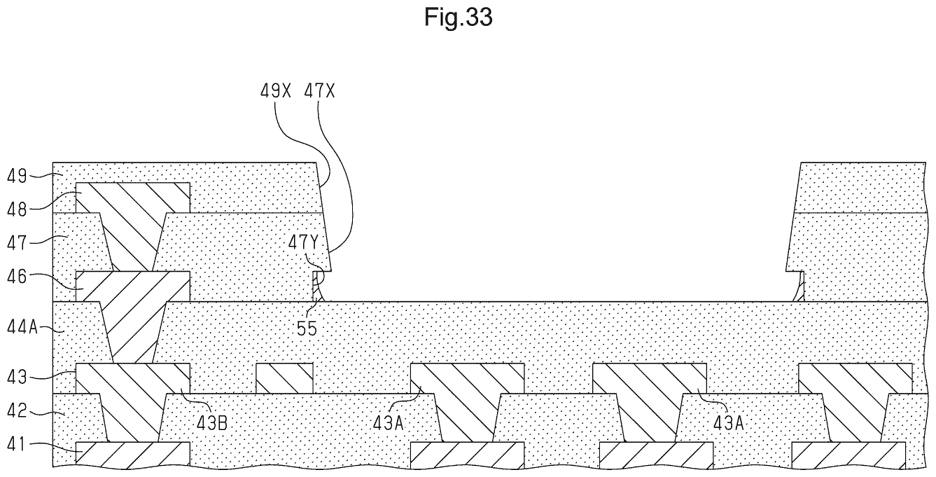

In the step illustrated in FIG. 33, steps similar to those illustrated in FIGS. 22 to 27 are performed to form the structural body illustrated in FIG. 33. The structural body has the through holes 47X and 49X extending through the insulation layers 47 and 49 in the thickness-wise direction and the recess 47Y formed at the lower end of the wall surface of the through hole 47X.

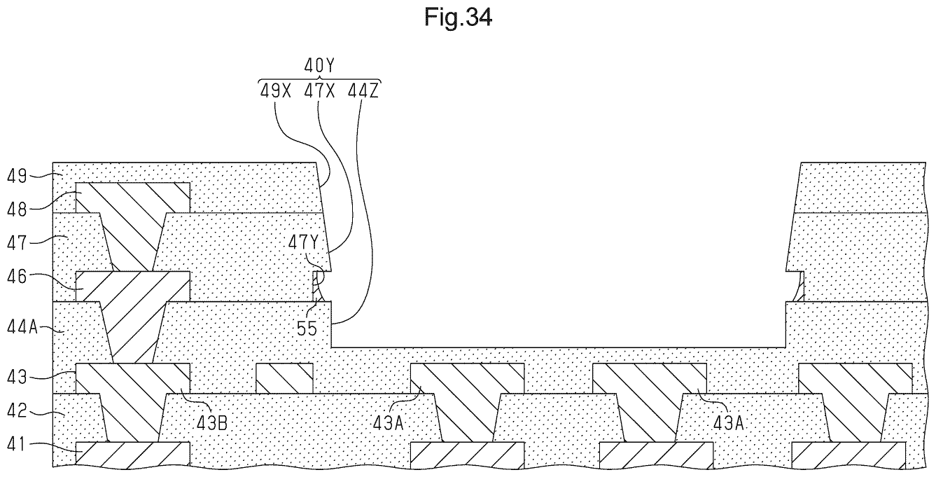

The insulation layer 44A exposed from the through holes 47X and 49X is thinned from the upper surface of the insulation layer 44A. That is, the insulation layer 44A that is exposed as a result of removal of the metal layer 55 is thinned from the upper surface of the insulation layer 44A. As illustrated in FIG. 34, this forms the recess 44Z recessed downward from the upper surface of the insulation layer 44A. In this step, the through holes 47X and 49X and the recess 44Z form the cavity 40Y. The insulation layer 44A may be thinned by, for example, ashing (dry etching using oxygen plasma). At the same time as the insulation layer 44A is thinned, the insulation layer 49 may be thinned.

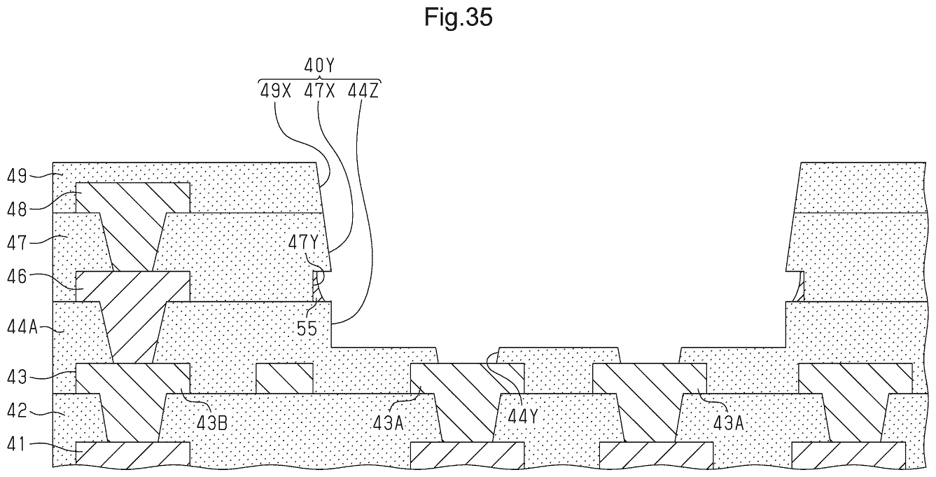

In the step illustrated in FIG. 35, a step similar to that illustrated in FIG. 15 is performed to form the openings 44Y at the bottom surface of the recess 44Z to expose parts of the upper surface of the wiring layer 43A.

When the openings 44Y are formed by laser cutting, a desmear process is performed to remove resin smears from the surface of the wiring layer 43A exposed at the bottom of the openings 44Y.

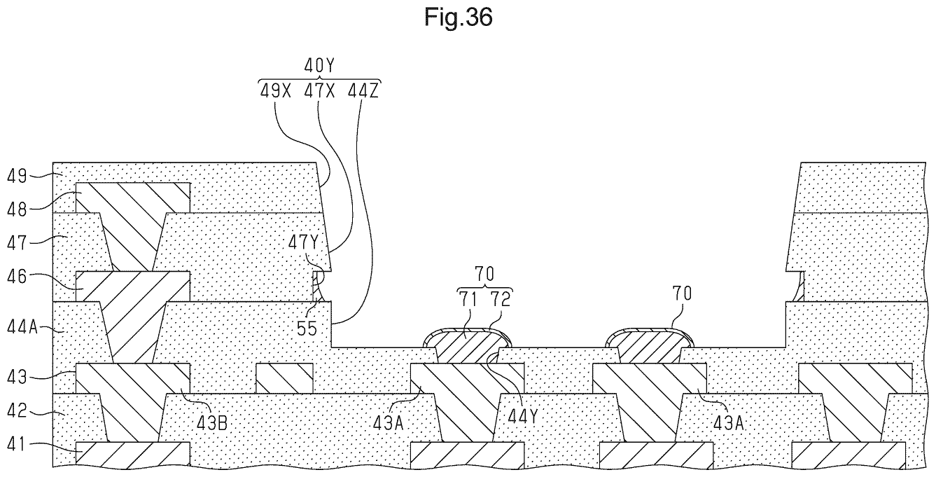

In the step illustrated in FIG. 36, a step similar to that illustrated in FIG. 16 is performed to form the connection terminals 70 on the upper surface of the wiring layer 43A exposed from the openings 44Y. The connection terminals 70 fill the openings 44Y and project upward from the bottom surface of the recess 44Z.

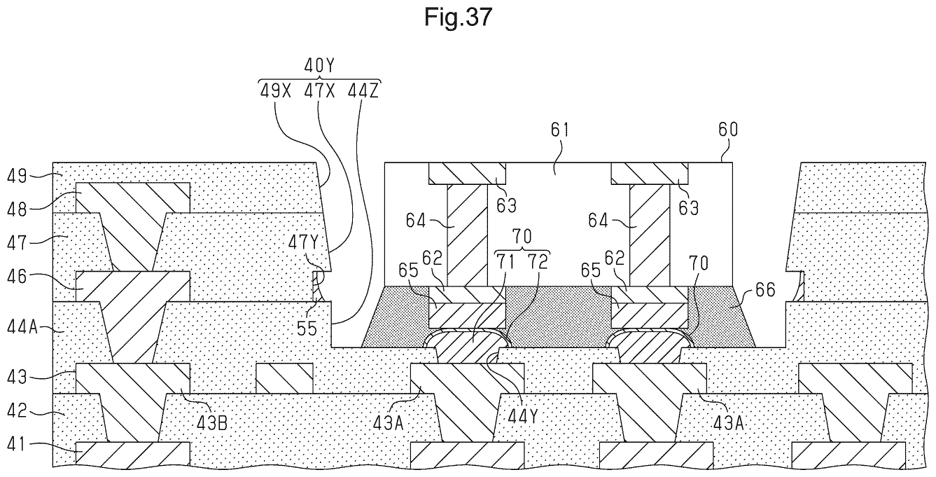

In the step illustrated in FIG. 37, a step similar to that illustrated in FIG. 17 is performed to mount the electronic component 60 on the connection terminals 70 in the cavity 40Y. Subsequently, the gap between the bottom surface of the cavity 40Y and the lower surface of the main body 61 of the electronic component 60 is filled with the underfill resin 66, and then the underfill resin 66 is cured. The underfill resin 66 may be applied in advance to the lower surface of the main body 61 of the electronic component 60. Then, when mounting the electronic component 60, the underfill resin 66 may fill the cavity 40Y to the bottom surface.

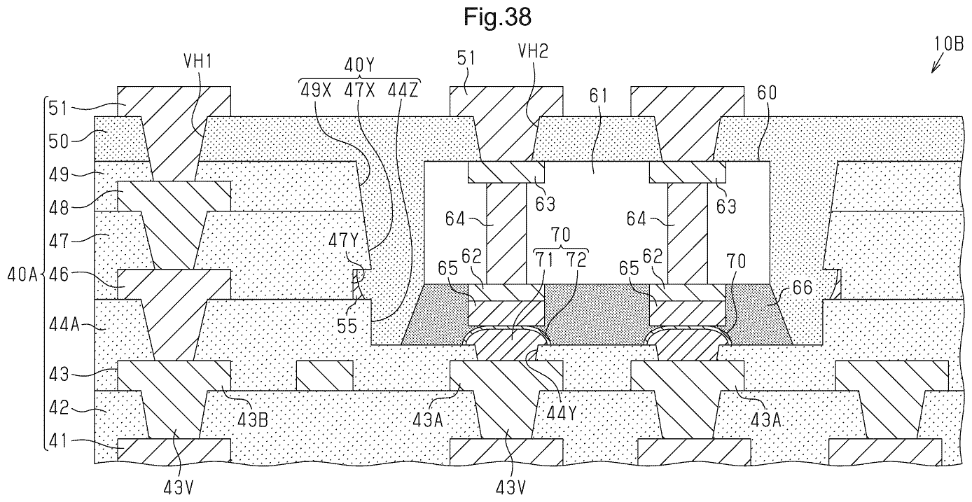

In the step illustrated in FIG. 38, steps similar to those illustrated in FIGS. 18 to 20 are performed to form the insulation layer 50 filling the cavity 40Y and form the wiring layer 51 on the upper surface of the insulation layer 50.

The manufacturing steps described above manufacture the structural body illustrated in FIG. 32.

In the present embodiment, the recess 47Y is an example of a third recess. The recess 44Z is an example of a fourth recess. The bottom surface of the recess 44Z is an example of a first surface.

### Operation and Advantages of the Third Embodiment

In addition to the operation and advantages (1-1) to (1-3) of the first embodiment and the operation and advantage (2-1) of the second embodiment, the present embodiment has the operation and advantages described below.

(3-1) In the wiring substrate 10B, the cavity 40Y includes the through holes 47X and 49X extending through the N number of (in this embodiment, two) insulation layers 47 and 49 in thickness-wise direction, and the recess 44Z formed in the upper surface of the insulation layer 44A exposed from the through holes 47X and 49X. The through holes 47X and 49X are continuous with the recess 44Z. With this structure, even when the thickness from the upper surface of the wiring layer 43B to the upper surface of the insulation layer 44A is relatively large, the thickness from the upper surface of the wiring layer 43A to the bottom surface of the recess 44Z is relatively small because of the recess 44Z. That is, the part of the insulation layer 44A covering the upper surface of the wiring layer 43A has a relatively small thickness. As a result, the depth of the openings 44Y is decreased. This, for example, facilitates formation of a structure in which the connection terminals 70 formed in the openings 44Y project upward from the bottom surface of the recess 44Z.

(3-2) The method for manufacturing the wiring substrate 10B includes forming the recess 44Z recessed downward from the upper surface of the insulation layer 44A by thinning the insulation layer 44A, exposed as a result of removal of the metal layer 55, from the upper surface of the insulation layer 44A. In this structure, the thinning process appropriately adjusts the thickness of the parts of the insulation layer 44A covering the upper surface of the wiring layer 43A.

### Fourth Embodiment

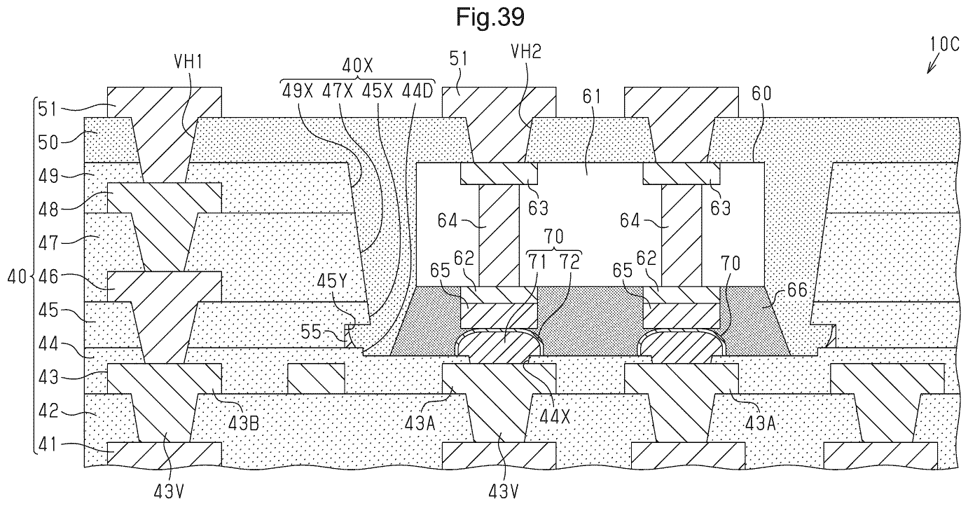

A fourth embodiment will now be described with reference to FIGS. 39 to 44. The differences from the first embodiment will be mainly discussed. The same reference numerals are given to those components that are the same as the corresponding components illustrated in FIGS. 1 to 38. Such components will not be described in detail.

As illustrated in FIG. 39, a wiring substrate 10C has a wiring structure 40 including the cavity 40X accommodating the electronic component 60. In the present embodiment, the cavity 40X is recessed from the upper surface of the insulation layer 49 to an intermediate part of the insulation layer 44 in the thickness-wise direction. The cavity 40X of the present embodiment includes through holes 45X, 47X, and 49X extending through the insulation layers 45, 47, 49 in the thickness-wise direction and a recess 44D formed in the upper surface of the insulation layer 44. The through holes 45X, 47X, and 49X are continuous with the recess 44D. In an example, the wall surface of the recess 44D extends orthogonal to the upper surface of the insulation layer 44. Alternatively, the wall surface of the recess 44D may include an inclined surface that is inclined toward the planar center of the recess 44D as the wall surface extends toward the bottom surface of the recess 44D. The bottom surface of the recess 44D, that is, the bottom surface of the cavity 40X, is located at an intermediate part of the insulation layer 44 in the thickness-wise direction. The bottom surface of the recess 44D is located above the upper surface of the wiring layer 43A and below the lower surface of the wiring layer 46.

As described above, in the wiring substrate 10C of the present embodiment, the four insulation layers 44, 45, 47, and 49 stacked on the insulation layer 42, which is the lowermost layer of the wiring structure 40, serve as insulation layers in which the cavity is formed.

In the present embodiment, the recess 45Y is arranged at an intermediate position of the wall surface of the cavity 40Y. The recess 45Y is arranged above the recess 44D. In other words, the recess 44D is recessed downward from the recess 45Y. In an example, a metal layer 55 is formed in the recess 45Y.

The openings 44X are formed at the bottom surface of the recess 44D to extend through the insulation layer 44A in the thickness-wise direction and expose parts of the upper surface of the wiring layer 43A. The openings 44X each have a depth that is, for example, smaller than that of the openings 44X of the first embodiment by the depth of the recess 44D. Each opening 44X is, for example, tapered so that the width decreases from the upper side (bottom surface of the recess 44D) toward the lower side (wiring layer 43A) as viewed in FIG. 39.

Connection terminals 70 are formed on the parts of the upper surface of the wiring layer 43A exposed from the openings 44X. In an example, the first metal layer 71 fills the openings 44X. In an example, the first metal layer 71 projects upward from the bottom surface of the recess 44D. The second metal layer 72 covers the entire surface of the first metal layer 71.

The electronic component 60 is, for example, flip-chip mounted on the wiring layer 43A exposed in the cavity 40X and the openings 44X. The underfill resin 66 fills the gap between the lower surface of the main body 61 of the electronic component 60 and the bottom surface of the cavity 40X, in this embodiment, the bottom surface of the recess 44D.

Although not illustrated, in the same manner as the wiring substrate 10 illustrated in FIG. 1, the insulation layer 52 and the wiring layer 53 are sequentially stacked on the upper surface of the insulation layer 50 of the wiring substrate 10C, and the external connection terminals 90 are formed on the upper surface of the wiring layer 53.

### Method for Manufacturing the Wiring Substrate 10C

A method for manufacturing the wiring substrate 10C will now be described. To facilitate understanding, portions that ultimately become elements of the wiring substrate 10C are indicated by reference characters used to denote the final elements.

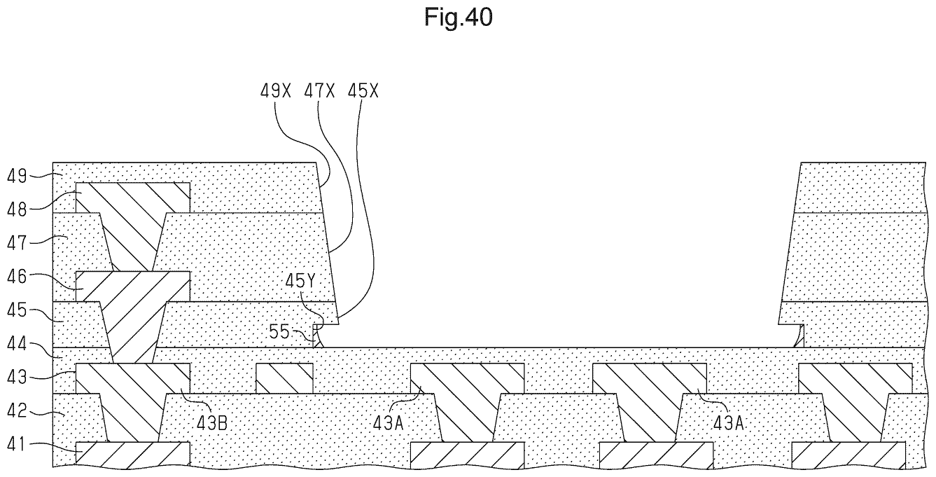

In the step illustrated in FIG. 40, steps similar to those illustrated in FIGS. 3 to 14 are performed to form the structural body illustrated in FIG. 40. The structural body has the through holes 45X, 47X, and 49X extending through the insulation layers 45, 47, and 49 in the thickness-wise direction, and the recess 45Y formed at the lower end of the wall surface of the through hole 45X.

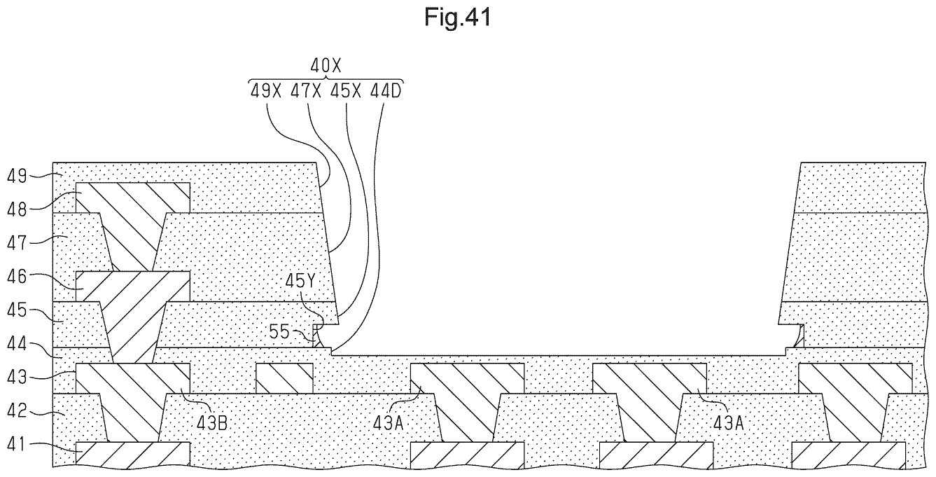

The insulation layer 44 exposed from the through holes 45X, 47X, and 49X is thinned from the upper surface of the insulation layer 44. That is, the insulation layer 44 that is exposed as a result of removal of the metal layer 55 is thinned from the upper surface of the insulation layer 44. As a result, as illustrated in FIG. 41, the recess 44D is recessed downward from the upper surface of the insulation layer 44. In this step, the through holes 45X, 47X, and 49X and the recess 44D form the cavity 40X. The insulation layer 44 may be thinned by, for example, ashing. At the same time as the insulation layer 44 is thinned, the insulation layer 49 may be thinned.

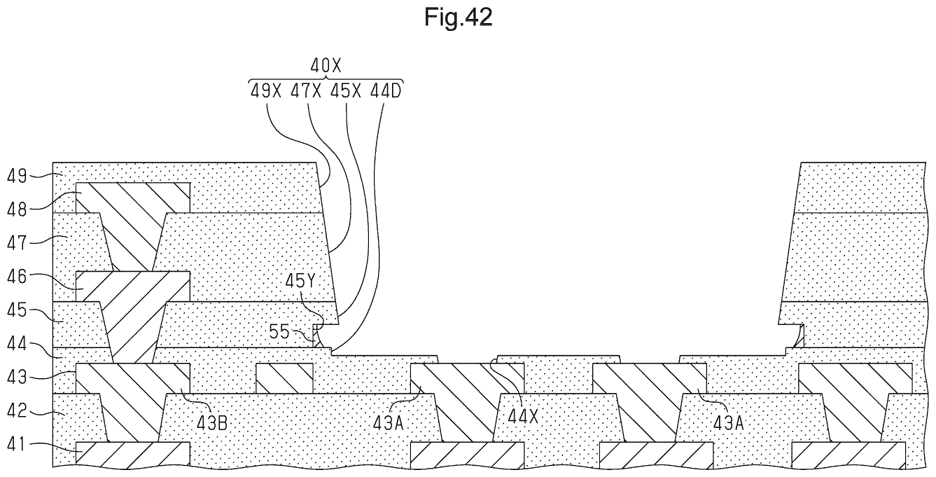

In the step illustrated in FIG. 42, a step similar to that illustrated in FIG. 15 is performed to form the openings 44X at the bottom surface of the recess 44D to expose parts of the upper surface of the wiring layer 43A.

When the openings 44X are formed by laser cutting, a desmear process is performed to remove resin smears from the surface of the wiring layer 43A exposed at the bottom of the openings 44X.

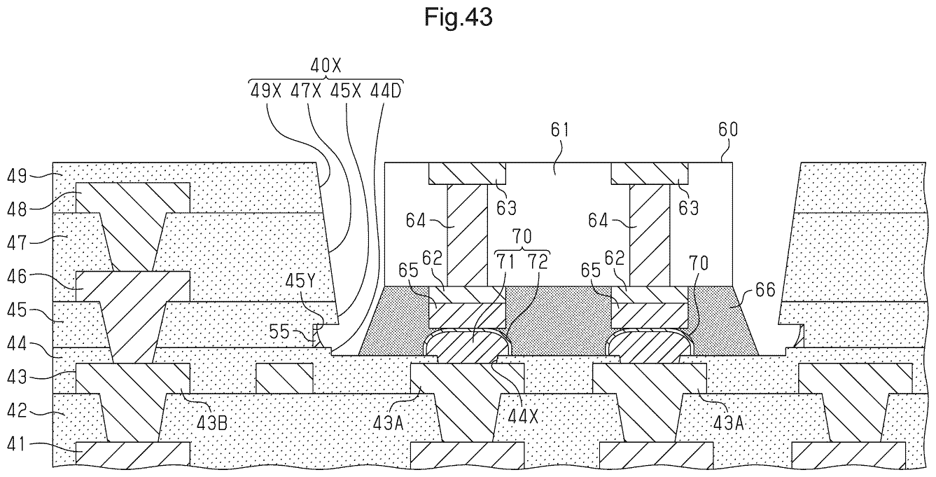

In the step illustrated in FIG. 43, a step similar to that illustrated in FIG. 16 is performed to form the connection terminals 70 on the upper surface of the wiring layer 43A exposed from the openings 44X. The connection terminals 70 fill the openings 44X and project upward from the bottom surface of the recess 44D.

Then, a step similar to that illustrated in FIG. 17 is performed to mount the electronic component 60 on the connection terminals 70 in the cavity 40X. Subsequently, the gap between the bottom surface of the cavity 40X and the lower surface of the main body 61 of the electronic component 60 is filled with the underfill resin 66, and then the underfill resin 66 is cured. The underfill resin 66 may be applied in advance to the lower surface of the main body 61 of the electronic component 60. Then, when mounting the electronic component 60, the underfill resin 66 may fill the cavity 40X to the bottom surface.

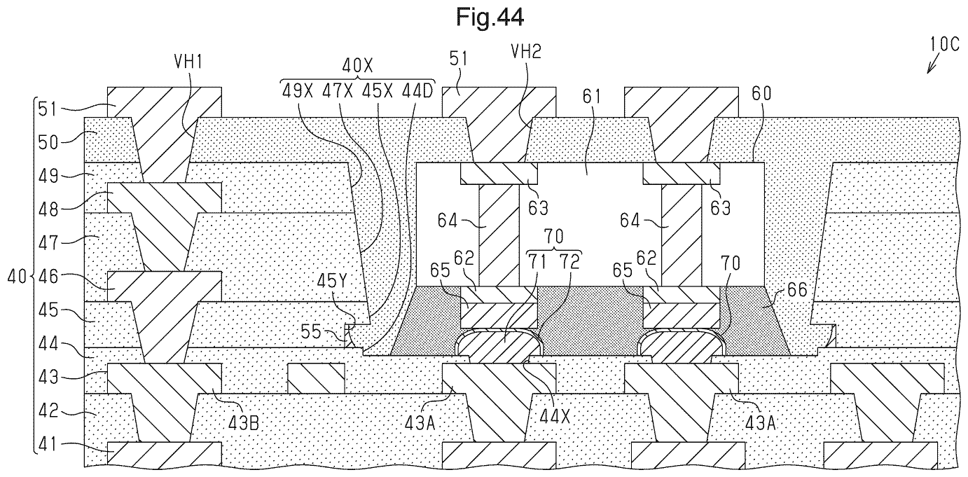

In the step illustrated in FIG. 44, steps similar to those illustrated in FIGS. 18 to 20 are performed to form the insulation layer 50 filling the cavity 40X and form the wiring layer 51 on the upper surface of the insulation layer 50.

The manufacturing steps described above manufacture the structural body illustrated in FIG. 39.

In the present embodiment, the recess 45Y is an example of a first recess. The recess 44D is an example of a second recess. The bottom surface of the recess 44D is an example of a first surface.

### Operation and Advantages of the Fourth Embodiment

The present embodiment has the same operation and advantages as described in (1-1) to (1-4) of the first embodiment and (3-1) and (3-2) of the third embodiment.

### Modified Examples

The embodiments described above may be modified as follows. The embodiments and the following modified examples may be combined as long as the combined modified examples remain technically consistent with each other.

In each embodiment, the structure of the connection terminals 70 may be changed. Modified examples of the connection terminals 70 in the first embodiment will be described below. In the same manner, the connection terminals 70 of the second, third, and fourth embodiments may also be changed.

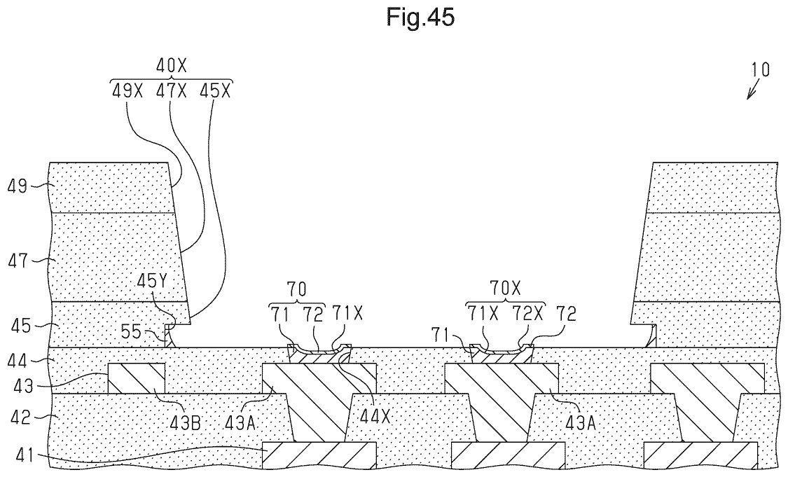

FIG. 45 illustrates an example of a structure in which the upper surface of each connection terminal 70 is changed to include a recess 70X recessed downward from the upper surface of the connection terminal 70. In this modified example, the first metal layer 71 includes a recess 71X that is recessed downward from the upper surface of the first metal layer 71. In an example, the first metal layer 71 fills the opening 44X. In an example, the upper surface of the first metal layer 71 is flush with the upper surface of the insulation layer 44. The second metal layer 72 covers the entire surface of the first metal layer 71. In an example, the second metal layer 72 covers the entire upper surface of the first metal layer 71 and the entire wall surface of the recess 71X. The second metal layer 72 is shaped in conformance with the upper surface of the first metal layer 71 and the wall surface of the recess 71X. Thus, the upper surface of the second metal layer 72 is recessed downward defining a recess 72X. As described above, the recess 71X and the recess 72X form the recess 70X.

In the modified example illustrated in FIG. 45, the upper surface of the first metal layer 71 may be located above the upper surface of the insulation layer 44 and may be located below the upper surface of the insulation layer 44.

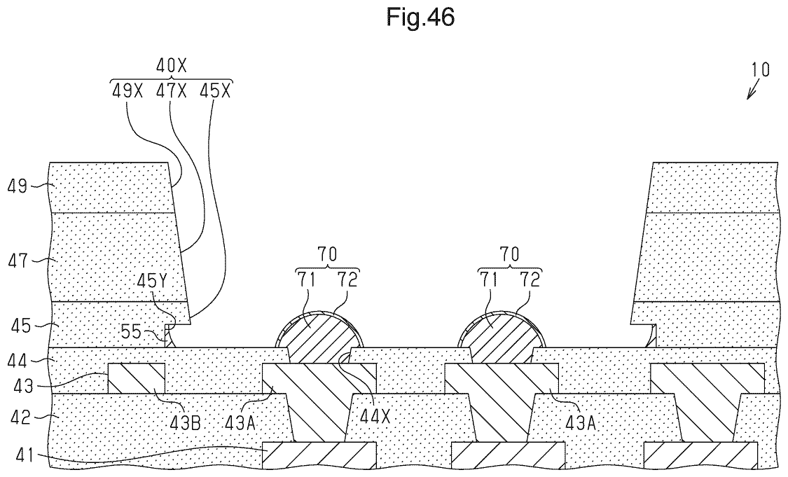

FIG. 46 illustrates an example of a structure in which the upper surface of each connection terminal 70 is changed to project upward. The upper surface of the connection terminal 70 may be curved upward toward the planar center of the connection terminal 70. In this modified example, the first metal layer 71 includes a portion projecting upward from the upper surface of the insulation layer 44 having a spherical surface. The second metal layer 72 covers the entire surface of the first metal layer 71. The surface of the second metal layer 72 is, for example, spherical.

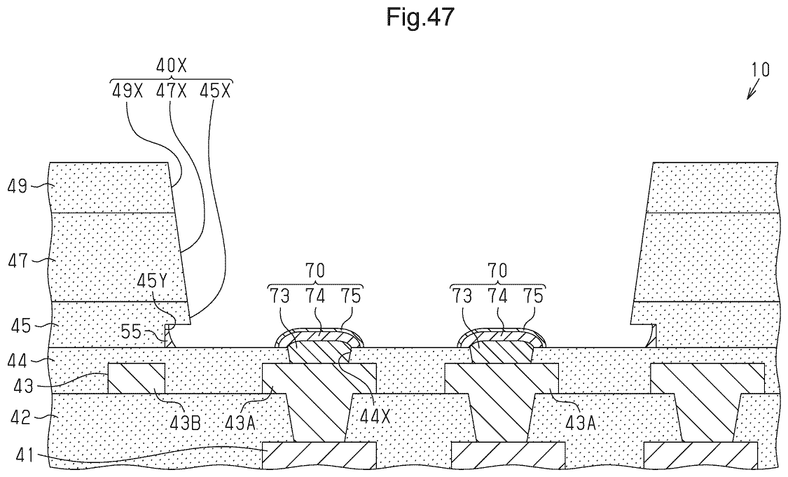

FIG. 47 illustrates an example of the connection terminal 70 changed to have a structure in which a first metal layer 73, a second metal layer 74, and a third metal layer 75 are sequentially stacked. The first metal layer 73 covers the entire upper surface of the wiring layer 43A exposed from the opening 44X. In an example, the first metal layer 73 fills the opening 44X. In an example, the first metal layer 73 projects upward from the upper surface of the insulation layer 44. The portion of the first metal layer 73 projecting upward from the upper surface of the insulation layer 44 is, for example, arranged at only a position overlapping the opening 44X in plan view. In other words, the portion of the first metal layer 73 projecting upward from the upper surface of the insulation layer 44 does not project outward from the opening 44X. In an example, the side surface of the first metal layer 73 exposed from the insulation layer 44 is curved to have an arcuate cross section. The upper surface of the first metal layer 73 is, for example, horizontally flat in the planar direction. The second metal layer 74 covers, for example, the entire surface of the first metal layer 73, that is, the upper surface and the side surface of the first metal layer 73. The second metal layer 74 is shaped in conformance with the surface of the first metal layer 73. The third metal layer 75 covers, for example, the entire surface of the second metal layer 74, that is, the upper surface and the side surface of the second metal layer 74. The third metal layer 75 is shaped in conformance with the surface of the second metal layer 74.

The material of the first metal layer 73 may be, for example, copper or a copper alloy. The first metal layer 73 may be, for example, an electrolytic plating layer formed by an electrolytic plating process. The material of the second metal layer 74 may be a conductive material having a higher adhesion to the first metal layer 73 than the metal forming the third metal layer 75. The second metal layer 74 is, for example, a Ni layer. The third metal layer 75 is, for example, an Au layer. The second metal layer 74 and the third metal layer 75 may each be, for example, an electroless plating layer formed by an electroless plating process or an electrolytic plating layer formed by an electrolytic plating process.

In the modified example illustrated in FIG. 47, the structure of the upper surface of the first metal layer 73 may be changed to include a recess that is recessed downward from the upper surface of the first metal layer 73. Alternatively, the upper surface of the first metal layer 73 may be changed to have a curved structure projecting upward.

In the embodiments, the structure of the wiring substrates 10, 10A, 10B, and 10C may be changed.

In the embodiments, each of the insulation layers 32, 34, 36, 38, 42, 47, 49, 50, and 52 may be a single layer formed of multiple resin layers as in the insulation layers 44 and 45.

In the embodiments, for example, the number of wiring layers, the layout of wiring, or the number of insulation layers in the wiring structure 30 may be modified in various manners.

In embodiments, the solder resist layer 80 may be omitted.

In the embodiments, the wiring structure 30 may be omitted.

In the embodiments, for example, the number of wiring layers, the layout of wiring, or the number of insulation layers in the wiring structures 40 and 40A may be modified in various manners.

In the wiring structures 40 and 40A of each embodiment, the number of insulation layers in which the cavity is formed may be changed.

In the embodiments, the metal layer 55 arranged in the recesses 45Y and 47Y may be omitted.

In the wiring substrates 10, 10A, 10B, and 10C of the embodiments, there is no limit to the number of wiring layers and the number of insulation layers that are stacked on the upper surface of the insulation layer 50 filling the cavity.

In the embodiments, the electronic component 22 incorporated in the core substrate 20 may be omitted.

In the embodiments, the wiring layers 41 and 31, which are located at the upper side and the lower side of the core substrate 20, are electrically connected to each other by the through-electrodes 21 filling the through holes 20X of the core substrate 20.

Alternatively, for example, the wiring layers 41 and 31, which are located at the upper side and the lower side of the core substrate 20, may be electrically connected to each other by a through hole plating layer formed on the wall of the through hole 20X. In this case, a resin may fill a space in the through hole 20X located at an inner side of the through hole plating layer.

The wiring substrates 10, 10A, 10B, and 10C of the embodiments are embodied in a build-up wiring substrate including the core substrate 20. However, there is no limitation to such a structure. For example, the wiring substrates 10, 10A, 10B, and 10C may be embodied in a coreless wiring substrate that does not include the core substrate 20.

There is no limit to the number of electronic components 60 incorporated in the wiring substrates 10, 10A, 10B, and 10C of the above embodiments. For example, multiple electronic components 60 may be incorporated in the wiring substrates 10, 10A, 10B, and 10C. In this case, the number of cavities 40X and 40Y may be the same as the number of incorporated electronic components 60. Alternatively, the multiple electronic components 60 may be arranged in a single cavity 40X or 40Y.

In the embodiments, the electronic component 60 including the through-electrode 64 is incorporated in the wiring substrates 10, 10A, 10B, and 10C. Alternatively, in an example, the electronic component 60 including the through-electrode 64 may be incorporated in the wiring substrates 10, 10A, 10B, and 10C.

In the embodiments, the wiring substrates 10, 10A, 10B, and 10C each incorporate the electronic component 60 having two types of electrodes, namely, the first electrode 62 and the second electrode 63. However, there is no limitation to such a structure. In an example, the electronic component 60 having three or more types of electrodes may be incorporated in the wiring substrates 10, 10A, 10B, and 10C.

In the above embodiments, the structure of the electronic component 60 may be changed. For example, the second electrodes 63 may be omitted. In this case, the electronic component 60 only includes the first electrodes 62 on the lower surface of the main body 61.

In the above embodiments, the present disclosure is embedded in a method for manufacturing a single unit (one unit) of a substrate. Instead, the present disclosure may be embedded in a method for manufacturing a batch of substrates.

### Clauses

This disclosure further encompasses the following embodiments.
1. A method for manufacturing a wiring substrate, the method including:
forming a first insulation layer;
forming a first wiring layer and a second wiring layer on an upper surface of the first insulation layer;
forming a second insulation layer on the upper surface of the first insulation layer to cover a side surface and an upper surface of the first wiring layer and a side surface and an upper surface of the second wiring layer;
forming a metal layer on an upper surface of the second insulation layer so that the metal layer overlaps the first wiring layer in plan view;
forming N number of insulation layers on the upper surface of the second insulation layer to cover the metal layer, where N is a natural number greater than or equal to 1;
forming a cavity in the N number of insulation layers through laser cutting so that the cavity exposes an upper surface of the metal layer;
removing the metal layer;
forming an opening in a first surface of the second insulation layer exposed at a bottom of the cavity so that the opening extends through the second insulation layer in a thickness-wise direction and exposes part of the upper surface of the first wiring layer;
forming a connection terminal on the upper surface of the first wiring layer exposed from the opening;
mounting an electronic component on the connection terminal in the cavity;
forming a capping insulation layer that fills the cavity and covers the electronic component; and
forming a third wiring layer on an upper surface of the capping insulation layer, in which
the first wiring layer overlaps the cavity in plan view, and
the second wiring layer does not overlap the cavity in plan view.
2. The method according to clause 1, further including:
subsequent to removing the metal layer, forming a recess that is recessed downward from an upper surface of the second insulation layer, which is exposed by removal of the metal layer, by thinning the second insulation layer from the upper surface of the second insulation layer,
in which the opening is formed at a bottom surface of the recess.

Various changes in form and details may be made to the examples above without departing from the spirit and scope of the claims and their equivalents. The examples are for the sake of description only, and not for purposes of limitation. Descriptions of features in each example are to be considered as being applicable to similar features or aspects in other examples. Suitable results may be achieved if sequences are performed in a different order, and/or if components in a described system, architecture, device, or circuit are combined differently, and/or replaced or supplemented by other components or their equivalents. The scope of the disclosure is not defined by the detailed description, but by the claims and their equivalents. All variations within the scope of the claims and their equivalents are included in the disclosure.

What is claimed is:

1. A wiring substrate comprising:
a first insulation layer;
a first wiring layer and a second wiring layer that are formed on an upper surface of the first insulation layer;
a second insulation layer formed on the upper surface of the first insulation layer to cover a side surface and an upper surface of the first wiring layer and a side surface and an upper surface of the second wiring layer;
N number of insulation layers stacked on an upper surface of the second insulation layer where N is a natural number greater than or equal to 1;
a cavity formed in the N number of insulation layers and exposing a first surface of the second insulation layer;
an opening formed in the first surface of the second insulation layer and extending through the second insulation layer in a thickness-wise direction to expose part of the upper surface of the first wiring layer;
a connection terminal formed on the upper surface of the first wiring layer exposed from the opening;
an electronic component arranged in the cavity and mounted on the connection terminal;
a capping insulation layer filling the cavity and covering the electronic component; and
a third wiring layer formed on an upper surface of the capping insulation layer, wherein
the first wiring layer overlaps the cavity in plan view, and
the second wiring layer does not overlap the cavity in plan view.

2. The wiring substrate according to claim 1, wherein the N number of insulation layers includes a third insulation layer formed on the upper surface of the second insulation layer, the wiring substrate further comprising:
a fourth wiring layer formed on an upper surface of the third insulation layer and electrically connected to the second wiring layer by a via wiring, the via wiring extending through the second insulation layer and the third insulation layer in the thickness-wise direction; and
a first recess formed in a lower end of the third insulation layer defining a wall surface of the cavity so that the first recess widens the cavity.

3. The wiring substrate according to claim 2, wherein
the cavity extends through the N number of insulation layers in the thickness-wise direction to expose part of the upper surface of the second insulation layer, and
the first surface is defined by the upper surface of the second insulation layer.

4. The wiring substrate according to claim 2, wherein the cavity includes
a through hole extending through the N number of insulation layers in the thickness-wise direction, and
a second recess formed in the upper surface of the second insulation layer exposed from the through hole and communicating with the through hole, the first surface is defined by a bottom surface of the second recess, and the second recess is arranged below the first recess.

5. The wiring substrate according to claim 1, wherein
the N number of insulation layers defines a stack of three insulation layers including a third insulation layer formed on the upper surface of the second insulation layer, and
the connection terminal includes an upper end that is exposed within the cavity, the upper end of the connection terminal being located below an upper surface of the third insulation layer.

6. The wiring substrate according to claim 1, wherein the N number of insulation layers includes a fourth insulation layer formed on the upper surface of the second insulation layer, the wiring substrate further comprising:
a fourth wiring layer formed on the upper surface of the second insulation layer and electrically connected to the second wiring layer by a via wiring, the via wiring extending through the second insulation layer in the thickness-wise direction; and
a third recess formed in a lower end of the fourth insulation layer defining a wall surface of the cavity so that the third recess widens the cavity, wherein the fourth insulation layer covers the fourth wiring layer.

7. The wiring substrate according to claim 6, wherein
the cavity includes
a through hole extending through the N number of insulation layers in the thickness-wise direction, and
a fourth recess formed in the upper surface of the second insulation layer exposed from the through hole and communicating with the through hole, the first surface is defined by a bottom surface of the fourth recess, and
the fourth recess is arranged below the third recess.

8. The wiring substrate according to claim 1, wherein
the N number of insulation layers defines a stack of two insulation layers including a fourth insulation layer formed on the upper surface of the second insulation layer, and
the connection terminal includes an upper end that is exposed within the cavity, the upper end of the connection terminal being located below an upper surface of the fourth insulation layer.

9. The wiring substrate according to claim 8, wherein
the upper end of the connection terminal is located below the upper surface of the second insulation layer.

10. The wiring substrate according to claim 1, wherein
the electronic component includes a main body, a first electrode arranged at a side of a lower surface of the main body, a second electrode arranged at a side opposite from the first electrode, and a through-electrode extending through the main body in a thickness-wise direction to electrically connect the first electrode and the second electrode,
the first electrode is electrically connected to the connection terminal by a bonding member, and
the third wiring layer is electrically connected to the second electrode.

11. The wiring substrate according to claim 1, wherein the connection terminal fills the opening and projects upward from the first surface.
